(19) United States
(12) Patent Application Publication
(10) Pub. No.: US 2026/0343298 A1
(43) Pub. Date: Oct. 29, 2026

(54) DEVICES AND METHODS FOR COMMUNICATION

(71) Applicant: NEC Corporation, Tokyo (JP)

(72) Inventors: Zhen HE, Beijing (CN); Peng GUAN, Beijing (CN); Gang WANG, Beijing (CN)

(73) Assignee: NEC Corporation, Tokyo (JP)

(21) Appl. No.: 19/491,086

(22) PCT Filed: Jun. 15, 2023
(86) PCT No.: PCT/CN2023/100485

§ 371 Date: Dec. 8, 2025

(51) Int. Cl. H04W 24/10; H04W 28/06

(52) U.S. Cl. CPC H04W 24/10; H04W 28/06

(57) ABSTRACT

Embodiments of the present disclosure provide a solution for channel state information (CSI) omission. In a solution, a first device truncates compressed bits corresponding to at least one layer of a plurality of layers until a first condition for stopping truncating compressed bits is met and based at least in part on at least one of the following: truncation size information, indicating the number of compressed bits corresponding to the plurality of layers truncated during the truncating, or effective length information, indicating the number of remaining compressed bits corresponding to the plurality of layers during the truncating. Then, the first device transmits the CSI report comprising the truncated compressed bits to a second device.

### FIELDS

Example embodiments of the present disclosure generally relate to the field of communication techniques and in particular, to devices and methods for channel state information (CSI) omission.

### BACKGROUND

As communication networks and services increase in size, complexity, and number of users, operations in the communication networks may become increasingly more complicated. In order to improve the communication performance, machine learning (ML)/artificial intelligence (AI) technology is proposed to be used in the wireless communication network.

Generally speaking, during the communication between the terminal device and the network device, the terminal device needs to report CSI feedback to the network device, such that the network device may understand the network condition and make a more proper subsequent schedule. Further, due to the introducing of multiple-input multiple-output (MIMO), the size of the reported CSI feedback increases dramatically. In this event, some CSI feedback may be dropped (i.e., omitted). However, if the CSI feedback dropping is improper, the network performance would be decreased accordingly.

### SUMMARY

In general, embodiments of the present disclosure provide a solution for CSI omission.

In a first aspect, there is provided a first device comprising: a processor configured to cause the first device to: truncate compressed bits corresponding to at least one layer of a plurality of layers until a first condition for stopping truncating compressed bits is met and based at least in part on at least one of the following: truncation size information, indicating the number of compressed bits corresponding to the plurality of layers truncated during the truncating, or effective length (EL) information, indicating the number of remaining compressed bits corresponding to the plurality of layers during the truncating; transmit, to a second device, the CSI report comprising the truncated compressed bits.

In a second aspect, there is provided a second device comprising: a processor configured to cause the second device to: generate configuration information for a channel status information (CSI) report, the configuration information indicating at least one of the following: an indication used for enabling or disabling truncating compressed bits corresponding to the plurality of layers, truncation size information, indicating the number of compressed bits corresponding to a plurality of layers truncated during the truncating, or effective length information, indicating the number of remaining compressed bits corresponding to the plurality of layers during the truncating; and transmit the configuration information to the first device.

In a third aspect, there is provided a first device comprising: a processor configured to cause the first device to: determine, a model from a plurality of models deployed at a second device based on at least one of the following: a plurality of respective numbers of compressed bits corresponding to the plurality of models, or a plurality of respective model identifiers corresponding to the plurality of models; and monitor the model determined from the plurality of models deployed at the second device.

In a fourth aspect, there is provided a communication method performed by a first device. The method comprises: truncating compressed bits corresponding to at least one layer of a plurality of layers until a first condition for stopping truncating compressed bits is met and based at least in part on at least one of the following: truncation size information, indicating the number of compressed bits corresponding to the plurality of layers truncated during the truncating, or effective length information, indicating the number of remaining compressed bits corresponding to the plurality of layers during the truncating; transmitting, to a second device, the CSI report comprising the truncated compressed bits.

In a fifth aspect, there is provided a communication method performed by a second device. The method comprises: generating configuration information for a channel status information (CSI) report, the configuration information indicating at least one of the following: an indication used for enabling or disabling truncating compressed bits corresponding to the plurality of layers, truncation size information, indicating the number of compressed bits corresponding to a plurality of layers truncated during the truncating, or effective length information, indicating the number of remaining compressed bits corresponding to the plurality of layers during the truncating; and transmitting the configuration information to the first device.

In a sixth aspect, there is provided a communication method performed by a first device. The method comprises: determining, a model from a plurality of models deployed at a second device based on at least one of the following: a plurality of respective numbers of compressed bits corresponding to the plurality of models, or a plurality of respective model identifiers corresponding to the plurality of models; and monitoring the model determined from the plurality of models deployed at the second device.

In a seventh aspect, there is provided a computer readable medium having instructions stored thereon, the instructions, when executed on at least one processor, causing the at least one processor to carry out the method according to the fourth, fifth, or sixth aspect.

Other features of the present disclosure will become easily comprehensible through the following description.

### BRIEF DESCRIPTION OF THE DRAWINGS

Through the more detailed description of some example embodiments of the present disclosure in the accompanying drawings, the above and other objects, features and advantages of the present disclosure will become more apparent, wherein:

FIG. 1A illustrates an example communication environment in which example embodiments of the present disclosure can be implemented;

FIG. 1B illustrates another example communication environment in which example embodiments of the present disclosure can be implemented;

FIG. 2 illustrates a signaling flow for communication in accordance with some embodiments of the present disclosure;

FIGS. 3A and 3B illustrate example blocks of truncating procedure;

FIG. 4 illustrates an example block of truncating procedure;

FIG. 5 illustrates an example block of truncating procedure;

FIGS. 6A and 6B illustrate example blocks of truncating procedure;

FIGS. 7A and 7B illustrate example blocks of truncating procedure;

FIG. 8 illustrates a flowchart of a method implemented at a first device according to some example embodiments of the present disclosure;

FIG. 9 illustrates a flowchart of a method implemented at a second device according to some example embodiments of the present disclosure;

FIG. 10 illustrates a flowchart of a method implemented at a first device according to some example embodiments of the present disclosure; and

FIG. 11 illustrates a simplified block diagram of an apparatus that is suitable for implementing example embodiments of the present disclosure.

Throughout the drawings, the same or similar reference numerals represent the same or similar element.

### DETAILED DESCRIPTION

Principle of the present disclosure will now be described with reference to some example embodiments. It is to be understood that these embodiments are described only for the purpose of illustration and help those skilled in the art to understand and implement the present disclosure, without suggesting any limitation as to the scope of the disclosure. Embodiments described herein can be implemented in various manners other than the ones described below.

In the following description and claims, unless defined otherwise, all technical and scientific terms used herein have the same meaning as commonly understood by one of ordinary skills in the art to which this disclosure belongs.

As used herein, the term ‘terminal device’ refers to any device having wireless or wired communication capabilities. Examples of the terminal device include, but not limited to, user equipment (UE), personal computers, desktops, mobile phones, cellular phones, smart phones, personal digital assistants (PDAs), portable computers, tablets, wearable devices, internet of things (IoT) devices, Ultra-reliable and Low Latency Communications (URLLC) devices, Internet of Everything (IoE) devices, machine type communication (MTC) devices, devices on vehicle for V2X communication where X means pedestrian, vehicle, or infrastructure/network, devices for Integrated Access and Backhaul (IAB), Space borne vehicles or Air borne vehicles in Non-terrestrial networks (NTN) including Satellites and High Altitude Platforms (HAPs) encompassing Unmanned Aircraft Systems (UAS), extended Reality (XR) devices including different types of realities such as Augmented Reality (AR), Mixed Reality (MR) and Virtual Reality (VR), the unmanned aerial vehicle (UAV) commonly known as a drone which is an aircraft without any human pilot, devices on high speed train (HST), or image capture devices such as digital cameras, sensors, gaming devices, music storage and playback appliances, or Internet appliances enabling wireless or wired Internet access and browsing and the like. The ‘terminal device’ can further has ‘multicast/broadcast’ feature, to support public safety and mission critical, V2X applications, transparent IPv4/IPv6 multicast delivery, IPTV, smart TV, radio services, software delivery over wireless, group communications and IoT applications. It may also incorporate one or multiple Subscriber Identity Module (SIM) as known as Multi-SIM. The term “terminal device” can be used interchangeably with a UE, a mobile station, a subscriber station, a mobile terminal, a user terminal or a wireless device.

The term “network device” refers to a device which is capable of providing or hosting a cell or coverage where terminal devices can communicate. Examples of a network device include, but not limited to, a Node B (NodeB or NB), an evolved NodeB (eNodeB or eNB), a next generation NodeB (gNB), a transmission reception point (TRP), a remote radio unit (RRU), a radio head (RH), a remote radio head (RRH), an IAB node, a low power node such as a femto node, a pico node, a reconfigurable intelligent surface (RIS), and the like.

The terminal device or the network device may have Artificial intelligence (AI) or Machine learning capability. It generally includes a model which has been trained from numerous collected data for a specific function, and can be used to predict some information.

The terminal device or the network device may work on several frequency ranges, e.g., FR1 (e.g., 450 MHz to 6000 MHz), FR2 (e.g., 24.25 GHz to 52.6 GHz), frequency band larger than 100A GHz as well as Tera Hertz (THz). It can further work on licensed/unlicensed/shared spectrum. The terminal device may have more than one connection with the network devices under Multi-Radio Dual Connectivity (MR-DC) application scenario. The terminal device or the network device can work on full duplex, flexible duplex and cross division duplex modes.

The embodiments of the present disclosure may be performed in test equipment, e.g., signal generator, signal analyzer, spectrum analyzer, network analyzer, test terminal device, test network device, channel emulator. In some embodiments, the terminal device may be connected with a first network device and a second network device. One of the first network device and the second network device may be a master node and the other one may be a secondary node. The first network device and the second network device may use different radio access technologies (RATs). In some embodiments, the first network device may be a first RAT device and the second network device may be a second RAT device. In some embodiments, the first RAT device is eNB and the second RAT device is gNB. Information related with different RATs may be transmitted to the terminal device from at least one of the first network device or the second network device. In some embodiments, first information may be transmitted to the terminal device from the first network device and second information may be transmitted to the terminal device from the second network device directly or via the first network device. In some embodiments, information related with configuration for the terminal device configured by the second network device may be transmitted from the second network device via the first network device. Information related with reconfiguration for the terminal device configured by the second network device may be transmitted to the terminal device from the second network device directly or via the first network device.

As used herein, the singular forms ‘a’, ‘an’ and ‘the’ are intended to include the plural forms as well, unless the context clearly indicates otherwise. The term ‘includes’ and its variants are to be read as open terms that mean ‘includes, but is not limited to.’ The term ‘based on’ is to be read as ‘at least in part based on.’ The term ‘one embodiment’ and ‘an embodiment’ are to be read as ‘at least one embodiment.’ The term ‘another embodiment’ is to be read as ‘at least one other embodiment.’ The terms ‘first,’ ‘second,’ and the like may refer to different or same objects. Other definitions, explicit and implicit, may be included below.

In some examples, values, procedures, or apparatus are referred to as ‘best,’ ‘lowest,’ ‘highest,’ ‘minimum,’ ‘maximum,’ or the like. It will be appreciated that such descriptions are intended to indicate that a selection among many used functional alternatives can be made, and such selections need not be better, smaller, higher, or otherwise preferable to other selections.

As used herein, the term “resource,” “transmission resource,” “uplink resource,” or “downlink resource” may refer to any resource for performing a communication, such as a resource in time domain, a resource in frequency domain, a resource in space domain, a resource in code domain, or any other resource enabling a communication, and the like. In the following, unless explicitly stated, a resource in both frequency domain and time domain will be used as an example of a transmission resource for describing some example embodiments of the present disclosure. It is noted that example embodiments of the present disclosure are equally applicable to other resources in other domains.

As discussed above, during the communication between the terminal device and the network device, the terminal device needs to report CSI feedback to the network device, such that the network device may understand the network condition and make a more proper subsequent schedule.

Further, due to the introducing of MIMO, the size of the reported CSI feedback increases dramatically. In this event, some CSI feedback may be dropped.

In the use case of CSI compression using two-sided model, the feasibility and methods to support the legacy CSI reporting principles need to be further discussed, such as, studying the priority rule regarding CSI collision handling and CSI omission.

In some embodiments, the two-sided model may refer to that a first part of the model is deployed at the UE side and a second part of the model is deployed at the network device, and the first and second parts may be cooperatively operated. As for the functionality of CSI compression, the first part of the model may be an encoder(s)/a CSI generation part, while the second part of the model may be a decoder(s)/a CSI reconstruction part.

Alternatively, in some embodiments, the two-sided model may refer to that a first model is deployed at the UE side and a second model is deployed at the network device, and the first and models may be cooperatively operated. As for the functionality of CSI compression, the first model may be a CSI encoder model/a CSI generation model, while the second model may be a CSI decoder model/a CSI reconstruction model.

In some embodiments, the AI/ML based CSI compression may be based on the legacy CSI feedback signaling framework. Further the following potential enhancements need to be further discussed: CSI-RS configurations, CSI reporting configurations, CSI report uplink control information (UCI) mapping/priority/omission, CSI processing procedures and so on.

In some embodiments, in the use case of CSI compression using two-sided model, use at least the following methods to support the priority rule regarding CSI omission: layer based priority rule or CSI payload reduction for a layer for layer specific and layer common model. Additionally, in some embodiments, CSI payload reduction for a layer may include different quantization method/granularity, different size of latent space, or CSI puncturing.

In summary, the CSI omission is agreed to be introduced. However, if the CSI omission is improper, the network performance would be decreased accordingly.

According to the example embodiments of the present discourse, a solution for CSI omission is proposed. In this solution, a first device (such as, a terminal device) truncates compressed bits corresponding to at least one layer of a plurality of layers until a first condition for stopping truncating compressed bits is met. In particular, the truncating is performed based at least in part on at least one of the following: truncation size information, indicating the number of compressed bits corresponding to the plurality of layers truncated during the truncating, or effective length information, indicating the number of remaining compressed bits corresponding to the plurality of layers during the truncating. Then, the first device transmits the CSI report comprising the truncated compressed bits to a second device (such as, a network device).

In this way, the operations about how to truncate compressed bits are well stipulated. Moreover, the compressed bits are truncated properly, which enable a trade-off between the resource efficiency and communication performance.

For better descriptions, some parameters used herein are listed as below:
C_{UL-SCH} is the number of code blocks for uplink shared channel (UL-SCH) of the physical uplink shared channel (PUSCH) transmission;
Kᵣ is the r-th code block size for UL-SCH of the PUSCH transmission;

$${N}_{symbol , all}^{PUSCH}$$

is the total number of orthogonal frequency division multiplexing (OFDM) symbols for UL-SCH of the PUSCH transmission;

$${M}_{sc}^{UCI} ( l )$$

is the number of resource elements that can be used for transmission of UCI in OFDM symbol l, for

$$l = 0 , 1 , 2 , … , {N}_{symb , all}^{PUSCH} - 1 ,$$

in the PUSCH transmission and

$${N}_{symb , all}^{PUSCH}$$

is the total number of OFDM symbols of the PUSCH, including all OFDM symbols used for DMRS;
for any OFDM symbol that carries DMRS of the PUSCH,

$${M}_{sc}^{UCI} ( l ) = 0 ;$$

for any OFDM symbol that does not carry DMRS of the PUSCH,

$${M}_{sc}^{UCI} ( l ) = {M}_{sc}^{PUSCH} - {M}_{sc}^{PT - RS} ( l ) ,$$

where

$${M}_{sc}^{PT - RS} ( l )$$

is the number of subcarriers in OFDM symbol/that carries phase-tracking reference signals (PT-RS), in the PUSCH transmission;
α is configured by higher layer parameter scaling;

$${Q}_{ack / CG - UCI}^{′}$$

may be either

$${Q}_{CG - UCI}^{′} or {Q}_{ACK}^{′} ;$$

$${Q}_{CG - UCI}^{′}$$

is the number of coded modulation symbols per layer for configured grant uplink control information (CG-UCI) transmission;

$${Q}_{ACK}^{′}$$

is the number of coded modulation symbols per layer for hybrid automatic repeat request-acknowledgement (HARQ-ACK) and CG-UCI transmission;

$${Q}_{CSI - 1}^{′}$$

is the number of coded modulation symbols per layer for CSI part 1 transmission;
L_{CSI-2} is the number of CRC bits for CSI part 2;
O_{CSI-2} is the number of bits for CSI part 2,

$${β}_{offset}^{PUSCH}$$

is configured by a higher layer parameter,
SumofallELs refer to a sum value of a plurality of effective lengths corresponding to the plurality of layers.

Further, for better descriptions, some terms used herein are listed as below:
As used herein, the term “model” is referred to as an association between an input and an output learned from training data, and thus a corresponding output may be generated for a given input after the training. The generation of the model may be based on an ML technique. The ML techniques may also be referred to as AI techniques. In general, an ML model can be built, which receives input information and makes predictions based on the input information.
As used herein, the “model monitoring” is referred to as a procedure that monitors the inference performance of the AI/ML model.
As used herein, the term “truncate (compressed bits)” is referred to at least one of: making the compressed bits shorter, shortening the compressed bits, cutting off the compressed bits, reducing or lessening the size/length of the compressed bits, removing partial or all bits of the compressed bits, omitting partial or all bits of the compressed bits, making the length of compressed bits smaller.
As used herein, the term “a first condition” is referred to as a criterion for stopping truncating compressed bits. That is, if the first condition is met, truncating compressed bits may be stopped. In some embodiments, the first condition may comprise one or more rules. Example rules include but are not limited to:
1) for each layer, whether all compressed bits corresponding to the layer have been truncated;
2) for each layer, whether the number of remaining compressed bits corresponding to the layer is equal to or smaller than a threshold number;
3) whether the total number of remaining compressed bits corresponding to the plurality of layers satisfies the requirements of available resources for transmitting compressed bits; Specifically, it is to determine whether “resources (e.g., PUSCH/PUCCH resource) required for compressed bits is less than or equal to available/configurable resources for compressed bits”, or “code rate for compressed bits is less than or equal to the one configured by higher layer parameter maxCodeRate”, which may be represented as below:

$$⌈ ( {O}_{CSI - 2} + {L}_{CSI - 2} ) \cdot {β}_{offset}^{PUSCH} \cdot {\sum }_{i = 0}^{{N}_{symb , all}^{PUSCH} - 1} {M}_{sc}^{UCI} ( l ) / {\sum }_{i = 0}^{{C}_{UL - SCH} - 1} {K}_{r} ⌉ \leq ⌈ α \cdot {\sum }_{i = 0}^{{N}_{symb , all}^{PUSCH} - 1} {M}_{sc}^{UCI} ( l ) ⌉ - {Q}_{ACK / CG - UCI}^{′} - {Q}_{CSI - 1}^{′} ,$$

where the variable on the left can be called “number of coded modulation symbols for CSI part 2 transmitted on the PUSCH”, the variable on the right can be called “number of available/configurable coded modulation symbols for CSI part 2 transmitted on the PUSCH”.
As used herein, the term “a second condition” is referred to as a criterion for stopping truncating compressed bits corresponding to a layer. That is, if the second condition is met, truncating compressed bits for a layer may be stopped. In some embodiments, the second condition may comprise one or more rules. Example rules include but are not limited to:
1) for the layer, whether all compressed bits corresponding to the layer have been truncated;
2) for the layer, whether the number of remaining compressed bits corresponding to the layer is equal to or smaller than a threshold number;
As used herein, the term “a third condition” is referred to as a criterion for continuing truncating compressed bits. That is, if the third condition is met, truncating compressed bits may continue to be performed. In some embodiments, the third condition may be a criterion opposite to the first condition. For example,
whether “resources (e.g., PUSCH/PUCCH resource) required for compressed bits is larger than available/configurable resources for compressed bits”, or “code rate for compressed bits is larger than the one configured by higher layer parameter maxCodeRate”, which may be represented as below:

$$⌈ ( {O}_{CSI - 2} + {L}_{CSI - 2} ) \cdot {β}_{offset}^{PUSCH} \cdot {\sum }_{i = 0}^{{N}_{symb , all}^{PUSCH} - 1} {M}_{sc}^{UCI} ( l ) / {\sum }_{i = 0}^{{C}_{UL - SCH} - 1} {K}_{r} ⌉ > ⌈ α \cdot {\sum }_{i = 0}^{{N}_{symb , all}^{PUSCH} - 1} {M}_{sc}^{UCI} ( l ) ⌉ - {Q}_{ACK / CG - UCI}^{′} - {Q}_{CSI - 1}^{′} ,$$

where the variable on the left can be called “number of coded modulation symbols for CSI part 2 transmitted on the PUSCH”, the variable on the right can be called “number of available/configurable coded modulation symbols for CSI part 2 transmitted on the PUSCH”.

In the context of the present disclosure, some terms may be used interchangeably, which are illustrated as below.
As used herein, a model may be equivalent to at least one of the following: an AI/ML model, an ML model, an AI model, a data-driven, a data processing model, an algorithm, a functionality, a procedure, a process, an entity, a function, a feature, a feature group, a model ID, a functionality ID, a configuration ID, a scenario ID, a site ID, a dataset ID, a pairing (model) ID, an encoder (model) ID, an decoder (model) ID. As a result, the above terms may be used interchangeably.
As used herein, the term of “encoder” is equivalent to a CSI generation model or a CSI generation part.
As used herein, the term of “decoder” is equivalent to a CSI reconstruction model or a CSI reconstruction part.
As used herein, the term of “quantization” is equivalent to quantizer or quantification, and it may be used to convert a group of floating-point variables to a group of binary variables. Quantization may be embedded within model or encoder.
As used herein, the term of “dequantization” is equivalent to dequantizer or dequantification, and it may be used to convert a group of binary variables to a group of floating-point variables. Dequantization may be embedded within model or decoder.
As used herein, the term of “compressed bits” is equivalent to encoded bits, quantization bits, bits, (AI/ML) CSI, (AI/ML) CSI part 2, (AI/ML) precoding matrix indicator (PMI), output CSI, or latent space. Further, the compressed bits consist of one or more binary variables or bits (e.g., 0, 1).
As used herein, the term of “truncation size” is equivalent to “truncation granularity”.
As used herein, the terms “layer” is equivalent to “transmission layer”.
As used herein, the terms “truncate”, “punch”, “perforate”, “puncture”, “prune”, “omit”, “cut out/off”, “shorten”, “clip”, “crop”, or “curtail”, or “abbreviate” may be used interchangeably.
As used herein, the terms “Length” is equivalent to “size” or “number” may be used interchangeably.
As used herein, the terms “indication”, “identifier” or “ID” may be used interchangeably.
As used herein, “UE capability” comprises but is not limited to “UE radio access capability”, or “UE assistance information, UAI”.

Further, wordings of “comprise”, “include” and “indicate” are equivalent with each other. Wordings of “corresponding to”, “associated with”, “mapping to/with”, and “for” are equivalent with each other. Wordings of “equivalent to”, “interchangeable” and “replaceable” are equivalent with each other.

In the present disclosure, the model or quantization is used to determine or calculate the compressed bits based on the measured channel or measured CSI.

It should be understood that although some embodiments are discussed with respect to a layer(s), the layer may be replaced by “subband” or “port”, and such replacement will not impact the implantation of the embodiments. In summary, the truncating operation may be performed with respect to “subband(s)” or “port(s)”.

Principles and implementations of the present disclosure will be described in detail below with reference to the figures.

### Example Environment

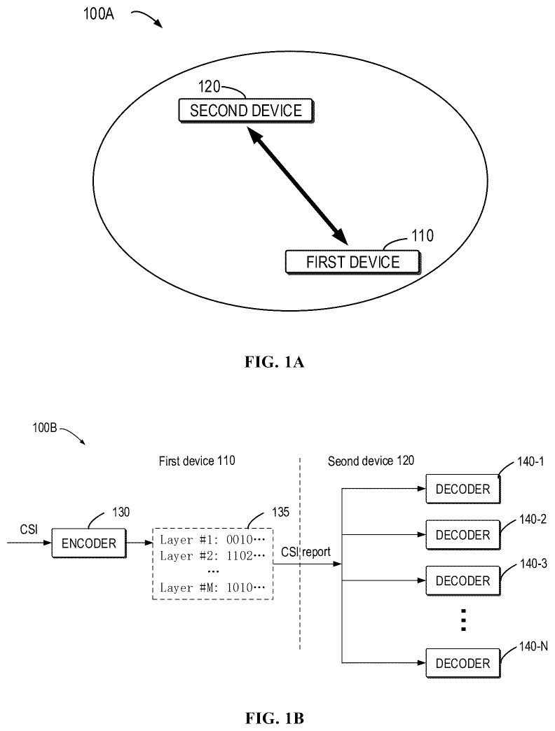

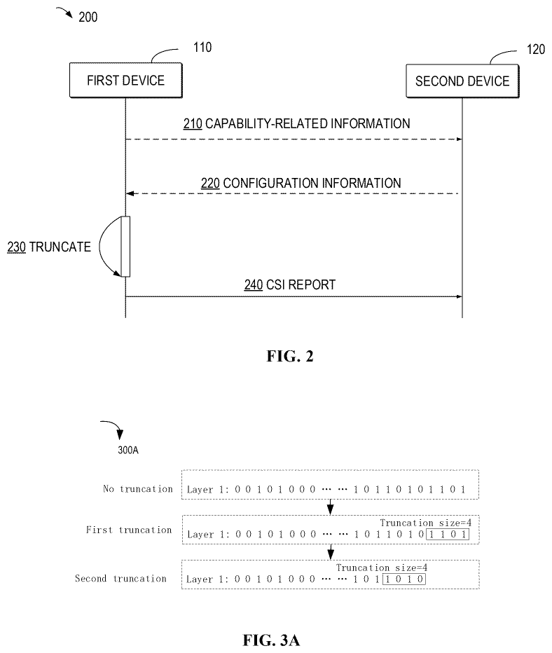

FIG. 1A illustrates a schematic diagram of an example communication environment 100A in which example embodiments of the present disclosure can be implemented. In the communication environment 100A, a plurality of communication devices, including a first device 110 and a second device 120, can communicate with each other.

In the example of FIG. 1A, in some embodiments, the first device 110 may include a terminal device and the second device 120 may include a network device serving the terminal device. In this specific example embodiment, a link from the first device 110 to the second device 120 is referred to as uplink, while a link from the second device 120 to the first device 110 is referred to as a downlink.

Further, multiple input multiple output (MIMO) is supported in the communication environment 100A, such that the second device 120 and the first device 110 may communicate with each other via different beams to enable a directional communication.

In downlink, the second device 120 is a transmitting (TX) device (or a transmitter) and the first device 110 is a receiving (RX) device (or a receiver), and the second device 120 may transmit downlink transmission to the first device 110. Correspondingly, in uplink, the second device 120 is an RX device (or a receiver) and the first device 110 is a TX device (or a transmitter), and the first device 110 may transmit uplink transmission to the second device 120.

It is to be understood that the number of devices and their connections shown in FIG. 1A are only for the purpose of illustration without suggesting any limitation. The communication environment 100A may include any suitable number of devices configured to implementing example embodiments of the present disclosure.

In some embodiments, the first device 110 and the second device 120 may communicate with each other via a channel such as a wireless communication channel on an air interface (e.g., Uu interface) or a PC5 interface. The wireless communication channel may comprise a sidelink, a physical uplink control channel (PUCCH), a physical uplink shared channel (PUSCH), a physical random-access channel (PRACH), a physical downlink control channel (PDCCH), a physical downlink shared channel (PDSCH) and a physical broadcast channel (PBCH). Of course, any other suitable channels are also feasible.

The communications in the communication environment 100A may conform to any suitable standards including, but not limited to, Global System for Mobile Communications (GSM), Long Term Evolution (LTE), LTE-Evolution, LTE-Advanced (LTE-A), New Radio (NR), Wideband Code Division Multiple Access (WCDMA), Code Division Multiple Access (CDMA), GSM EDGE Radio Access Network (GERAN), Machine Type Communication (MTC) and the like. The embodiments of the present disclosure may be performed according to any generation communication protocols either currently known or to be developed in the future. Examples of the communication protocols include, but not limited to, the first generation (1G), the second generation (2G), 2.5G, 2.75G, the third generation (3G), the fourth generation (4G), 4.5G, the fifth generation (5G) communication protocols, 5.5G, 5G-Advanced networks, or the sixth generation (6G) networks.

In FIG. 1A, CSI may be provided from the first device 110 to the second device 120, which will be discussed with reference to FIG. 1B. FIG. 1B illustrates environment 100B in which example embodiments of the present disclosure can be implemented. For the purposes of discussion, the environment 100B will be discussed with reference to FIG. 1A.

In FIG. 1B, an encoder 130 may be deployed at the first device 110. The encoder 130 may encode the CSI into compressed bits. As illustrated in FIG. 1B, in case of MIMO, the compressed bits may correspond to one or more layers. The one or more layers may be determined by the first device 110 based on a CSI configuration transmitted by the second device 120. For example, the second device 120 indicates to the first device 110 that compressed bits corresponding to layers 1, 2, 3 and 4 may be reported. Based on this configuration, the first device 110 may further determine to report compressed bits corresponding to layers 1, 2 and 3.

In FIG. 1B, more than one decoder, such as, decoder 140-1, 140-2, 140-3, . . . , 140-N, may be deployed at the second device 120, where N is an integer larger than 1. In some embodiments, in FIG. 1B, different decoders 140 may be used for decoding different sizes of compressed bits.

Generally, when the reported rank indicator (i.e., RI) is larger than 1, the first device 110 needs to report compressed bits corresponding to multiple layers, where each layer is corresponding to a set of compressed bits. In this event, when the CSI payload size (i.e., resources required for transmitting the CSI report comprising the compressed bits) is larger than available resources (such as, UL transmission resources), the CSI payload truncation (called “truncation” for short, i.e., CSI omission) is needed.

When performing truncating, it would be desirable to understand how to truncate the compressed bits corresponding to multiple layers. In particular, it would be desirable to understand the details about the truncation type, truncation method, truncation order and so on.

According to the example embodiments of the present discourse, a solution for CSI omission is proposed. In this solution, a first device truncates compressed bits corresponding to at least one layer of a plurality of layers until a first condition for stopping truncating compressed bits is met and based at least in part on at least one of the following: truncation size information, indicating the number of compressed bits corresponding to the plurality of layers truncated during the truncating, or effective length information, indicating the number of remaining compressed bits corresponding to the plurality of layers during the truncating. Then, the first device transmits the CSI report comprising the truncated compressed bits to a second device.

In this way, how truncate compressed bits may be well stipulated. Moreover, the compressed bits may be truncated properly, which enable a trade-off between the resource efficiency and communication performance.

### Example Processes

Reference is made to FIG. 2, which illustrates a signaling flow 200 for communication in accordance with some embodiments of the present disclosure. For the purposes of discussion, the signaling flow 200 will be discussed with reference to FIG. 1A and FIG. 1B, for example, by using the first device 110 and the second device 120.

In the following descriptions, while operations are depicted in a particular order, this should not be understood as requiring that such operations be performed in the particular order shown or in sequential order, or that all illustrated operations be performed, to achieve desirable results. In certain circumstances, multitasking and parallel processing may be advantageous. Likewise, while several specific implementation details are contained in the above discussions, these should not be construed as limitations on the scope of the present disclosure, but rather as descriptions of features that may be specific to particular embodiments. Certain features that are described in the context of separate embodiments may also be implemented in combination in a single embodiment. Conversely, various features that are described in the context of a single embodiment may also be implemented in multiple embodiments separately or in any suitable sub-combination.

It is to be understood that the operations at the first device 110 and the second device 120 should be coordinated. In other words, the second device 120 and the first device 110 should have common understanding about configurations, parameters and so on. Such common understanding may be implemented by any suitable interactions between the second device 120 and the first device 110 or both the second device 120 and the first device 110 applying the same rule/policy. In the following, although some operations are described from a perspective of the first device 110, it is to be understood that the corresponding operations should be performed by the second device 120. Similarly, although some operations are described from a perspective of the second device 120, it is to be understood that the corresponding operations should be performed by the first device 110. Merely for brevity, some of the same or similar contents are omitted here.

In addition, in the following description, some interactions are performed among the first device 110 and the second device 120 (such as, exchanging first and second information and so on). It is to be understood that the interactions may be implemented either in one single signaling/message/configuration or multiple signaling/messages/configurations, including system information, radio resource control (RRC) signalling, downlink control information (DCI), uplink control information (UCI), media access control (MAC) control element (CE) and so on. The present disclosure is not limited in this regard.

In some embodiments, the first device 110 may be operated as a terminal device and the second device 120 may be operated as a network device. Alternatively, in some other embodiments, both the first and the second devices are terminal devices.

In operation, the first device receives 220 configuration information for a CSI report from a second device. The first device further truncates 230 compressed bits corresponding to at least one layer of a plurality of layers until a first condition for stopping truncating compressed bits is met and based at least in part on at least one of the following: truncation size information, indicating the number of compressed bits corresponding to the plurality of layers truncated during the truncating, or effective length information, indicating the number of remaining compressed bits corresponding to the plurality of layers during the truncating.

Then, the first device transmits 240 the CSI report comprising the truncated compressed bits to the second device.

Generally speaking, for a layer, the corresponding compressed bits may be truncated in the field indicating the compressed bits based on the following order: from right to left, from left to right, from the least significant bit (LSB) to the most significant bit (MSB), or from the MSB to the LSB. In some embodiments of the present discourse, the first device 110 may truncate the compressed bits according to an order of from right to left or from the least significant bit (LSB) to the most significant bit (MSB).

In some embodiments, a first part of the CSI report (i.e., CSI part 1) may comprise at least one of the following:
information about whether the truncating is performed,
information about identifier of one or more truncated layers,
information about the number of times of truncating operations,
information about a truncation size used by the first device 110,
information about a truncation step size used by the first device 110, or
information about an effective length (called as “EL” for short sometime) used by the first device 110.

In some embodiments, the compressed bits may be included in CSI part 2. In order to identify the number of compressed bits comprised in the CSI part 2, e.g., compressed bits corresponding to layers in CSI part 2, CSI part 1 may comprise at least one of the following information: a first indication about truncation, a second indication about (actual/residual/effective) CSI payload size (or size of CSI part 2, a size of compressed bits).

In some embodiments, the first indication may comprise at least one of the following: indication about whether the truncation is performed (per layer), indication about identifier of truncation layer, indication about the number of times for truncation (per layer), indication about truncation size (per layer or/and time), indication about truncation step size (per layer or/and time).

In some embodiments, the second indication may comprise at least one of the following: indication about effective length (per layer) or indication about a set of information, such as, a set of model information, a set of quantization information, a set of CSI payload information and so on.

In the present disclosure, if the first condition is met, the first device 110 may stop truncating compressed bits with respect to all the layers. Further if a second condition is met, the first device 110 may stop truncating compressed bits with respect to one specific layers.

In some embodiments, the first device 110 may determine the first condition is met in response to at least one of the following:
the total number of remaining compressed bits corresponding to the plurality of layers satisfies the requirements of available resources for transmitting compressed bits, or
for each of the plurality of layers, the number of remaining compressed bits meets a second condition for stopping truncating compressed bits corresponding to a layer.

In some embodiments, for all layers, the truncation will be stopped if at least one of the following: for each layer, the second condition is satisfied; or the first condition is satisfied.

In some embodiments, first device 110 may determine the second condition for stopping truncating compressed bits corresponding to a layer is met in response to at least one of the following:
all compressed bits corresponding to the layer have been truncated, or
the number of remaining compressed bits corresponding to the layer is equal to or smaller than a threshold number.

In some embodiments, for a layer, the truncation may be stopped if all compressed bits corresponding to the layer are truncated.

Alternatively, in some embodiments, for a layer, the truncation may be stopped if the length of residual compressed bits corresponding to the layer is equal to a smallest (effective) length of compressed bits.

Alternatively, in some embodiments, for a layer, the truncation mat be stopped if:

|Length of remaining compressed bits corresponding to the layer−Smallest length of compressed bits|≤Predefined threshold

In some embodiments, the smallest length of compressed bits or the predefined threshold may be provided by the second device 120 by using an RRC signalling, MAC CE or DCI.

Alternatively, in some embodiments, the smallest length of compressed bits or the predefined threshold may be reported from the first device 110 to the second device 120 as a UE capability. Optionally, the predefined threshold may be determined based on (e.g., equal to) the truncation size.

In some embodiments, the smallest length may be replaced with or determined based on a largest truncation size.

Alternatively, in some embodiments, for a layer, the truncation may be stopped if the first condition is met.

In the following, details about the truncation size information and effective length information will be discussed.

In some embodiments, the truncation size information may comprise at least one of the following:
a truncation size, indicating the number of compressed bits truncated from compressed bits corresponding to a layer of the plurality of layers for each truncating operation, wherein the truncation size is either a common size configured for the plurality of layers or a specific size configured for one of the plurality of layers,
a truncation step size, indicating a difference of truncation sizes of two consecutive truncating operations, wherein the truncation step size is either a common size configured for the plurality of layers or a specific size configured for one of the plurality of layers, or
a set of truncation sizes, indicating a set of allowed truncation sizes for a layer, wherein the set of truncation sizes is either a common set configured for the plurality of layers or a specific set configured for one of the plurality of layers.

In some embodiments, the effective length information may comprise:
an effective length, indicating the number of allowed remaining compressed bits for a layer of the plurality of layers, wherein the effective length is either a common effective length configured for the plurality of layers or a specific effective length configured for one of the plurality of layers, or
set of effective lengths, indicating a set of numbers of allowed remaining compressed bits for a layer of the plurality of layers, wherein the set of effective lengths is either a common set configured for the plurality of layers or a specific set configured for one of the plurality of layers.

It is to be clarified that any of the truncation size information and effective length information may be defined as a default value by the communication organization (such as 3GPP), or pre-defined by the network operator or service provider. In this way, no additional signaling is needed.

Alternatively, any of the truncation size information and effective length information may be configured by the second device 120.

In some embodiments, a first device 110 may be provided by the second device 120 with a first parameter (and the first parameter is configured as “enabled””). The first device 110 needs to perform truncation for the compressed bits (corresponding to multiple layers). Otherwise (or the first parameter is configured as “disabled”), The first device 110 needs to omit compressed bits corresponding to layers based on priorities of the layers.

That is, the first parameter (or the first parameter is configured as “enabled”) is used to indicate that UE may perform truncation (or enable truncation) when the third condition is satisfied.

As illustrated in FIG. 2, the second device may generate and transmit 220 the configuration information for a CSI report via an RRC signalling, a MAC CE or DCI, where the configuration information indicates at least one of the following:
an indication used for enabling or disabling truncating compressed bits corresponding to the plurality of layers,
truncation size information, indicating the number of compressed bits corresponding to a plurality of layers truncated during the truncating, or
effective length information, indicating the number of remaining compressed bits corresponding to the plurality of layers during the truncating.

That is, the second device 120 may provide potential RRC configuration to the first device 110.

In some embodiments, any of the truncation size information and the effective length information may be determined based on at least one of the following:
a rank indicator (RI),
an index of a layer,
parity of an index of a layer,
the number of compressed bits corresponding to a layer,
a truncation ratio,
model-related information associated with a layer,
quantization-related information associated with a layer, or
CSI payload information associated with a layer.

In some embodiments, the model-related information may comprise at least one of the following:
an identity of a model,
model description information,
data information corresponding to a mode,
performance of a model,
a configuration associated with a model,
a scenario associated with a model
a site associated with a model, or
a cell associated with a model.

In some embodiments, the quantization-related information may comprise at least one of the following:
an identity of a quantization,
a type of quantization,
a size of segment for vector quantization,
the number of segments for vector quantization,
information related to a codebook of quantization for vector quantization,
the number of quantization bits,
the number of quantization bits per segment for vector quantization,
a quantization granularity, or
performance of quantization.

In some embodiments, the CSI payload information may comprise at least one of the following:
an indication indicating a CSI payload size,
an indication indicating a size of compressed bits,
an indication indicating a size of second part of a CSI report, or
an indication indicating a compression ratio.

In some embodiments, the truncation size or truncation step size may be determined based on the following: defined to be a default or predefined value (e.g., 0, 1, 2, 3, 4,5, 6, 7, 8 and so on), be provided by the second device 120 by using an RRC signaling, a MAC CE or DCI.

In some embodiments, the truncation size or truncation step size may be determined based on or associated with a set of information, such as, a set of model information, a set of quantization information, a set of CSI payload information and so on.

In some embodiments, the truncation size (corresponding to a layer) may be determined based on the number/size of quantization bits (associated with the layer).

In some other embodiments, the truncation size (corresponding to a layer) may be determined based on the size of compressed bits (corresponding to the layer) and a truncation ratio, where the truncation ratio may be a default or predefined value, provided by the second device 120 by using an RRC signaling, a MAC CE or DCI, or determined based on a set of information, such as, a set of model information, a set of quantization information, a set of CSI payload information and so on.

Optionally, in some embodiments, the first device 110 may provide 210 its capability-related information to the second device 120, such that the second device 120 may determine more proper configuration information for the first device 110. In some embodiments, the capability-related information may indicate at least one of the following:
a first capability indicating whether the first device 110 supports truncating the compressed bits,
a second capability indicates the maximum or minimum value of a truncation size supported by the first device 110,
a third capability indicates the maximum or minimum value of a truncation step size supported by the first device 110, or
a fourth capability indicates the maximum or minimum value of an effective length supported by the first device 110.

In some embodiments, the first device 110 may provide potential UE capability to the second device 120. In some embodiments, the first device 110 may report to the second device 120 at least one of a first UE capability, a second UE capability, a third UE capability or a fourth capability, where the first UE capability indicates whether UE supports truncation of compressed bits, the second UE capability indicates the maximum or minimum value of the truncation size supported (or required) by the first device 110, the third UE capability indicates the maximum or minimum value of the truncation step size supported by the first device 110, the fourth UE capability indicates the smallest length of (available/significant/effective) compressed bits supported by the first device 110.

Additionally, priorities of different layers may be different. In some embodiments, a priority of a layer of the plurality of layers may be determined based on at least one of the following:
an index of a layer,
parity of an index of a layer,
quality of a layer,
the number of compressed bits corresponding to a layer,
model-related information associated with a layer,
quantization information associated with a layer, or
CSI payload information associated with a layer.

In some embodiments, for a layer, the first device 110 may determine the priority of the layer based on one or more factors.

One example factor may be index of the layer, e.g., the index of the first layer (i.e., Layer 1) may be 0, the index of the second layer (i.e., Layer 2) may be 1. For example, the larger the index of the layer, the higher the priority of the layer. Optionally, a priority rule may be pre-defined based on the index of the layer, e.g., Layer 1>Layer 3>Layer 2>Layer 4.

Another example factor may be parity (i.e., even or odd) of the layer. A further example factor may be quality of the layer, e.g., the layer with the highest quality may be called the strongest layer, the layer with the highest quality may be called the weakest layer.

A further example factor may be length of the compressed bits corresponding to the layer.

The other example factors may include but not be limited to, model information associated with the layer, Quantization information associated with the layer and CSI payload information associated with the layer.

In some embodiments, the model information associated with the layer.

Specifically, the model information comprises at least one of the following:
(Logical or physical) Model ID, e.g., model/global model/paired model/encoder (model)/decoder (model) ID, pairing ID;
Model description information or meta/assistance information, e.g., applicable condition;
Configuration/scenario/site/cell information associated with model, e.g., configuration/scenario/site/cell ID;
Data (or dataset) information corresponding to model, e.g., quality/ID/format/type/size of data/dataset, data categorization ID;
Performance of model, e.g., SGCS. The performance includes at least one of the performance of model inference, generalization, complexity or memory storage.

In some embodiments, the quantization information associated with the layer. Specifically, the quantization information comprises at least one of the following:
Quantization ID;
Type of quantization, e.g., scalar quantization (SQ), vector quantization (VQ), uniform quantization, non-uniform quantization;
Size of segment (for VQ);
The number of segments (for VQ);
Information (e.g., type, size, number, format) related to dictionary/codebook of quantization (for VQ);
The number/size of quantization bits, or number/size of quantization bits per segment (for VQ);
Quantization granularity (or resolution);
Performance of quantization, e.g., performance, complexity, memory storage.

In some embodiments, the CSI payload information may be associated with a layer. In some embodiments, the CSI payload information may comprise at least one of the following: an indication of CSI payload size (corresponding to the layer), an indication of size of compressed bits (corresponding to the layer), an indication of CSI part 2 (corresponding to the layer), or an indication of compression ratio (corresponding to the layer).

In some embodiments, the first device 110 may determine the priority of the layer based on a predefined priority rule. Where the predefined priority rule is specified based on at least one of the above information. For example, if “index of layer” is adopted, the predefined priority rule can be as follows: the smaller the index of the layer, the higher the priority of the layer; or the larger the index of the layer, the higher the priority of the layer.

In some embodiments, the first device 110 may determine the priority of the layer based on a priority value corresponding to the layer. Where the priority value may be determined based on a predefined formula.

In some embodiments, a predefined formula is specified based on at least one of the above information. In other words, the variables (including independent and dependent variables) in the predefined formula are determined based on at least one of the above information.

In should be understood that the priority of layer may also not be specified, i.e., the priority of layer does not need to be determined before truncation. For example, the compressed bits corresponding to the layer with the smaller index of layer will be prioritized to be truncated.

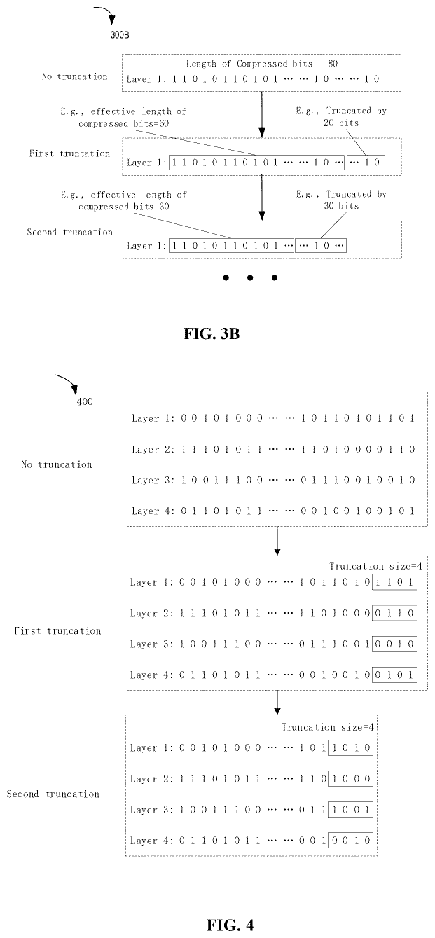

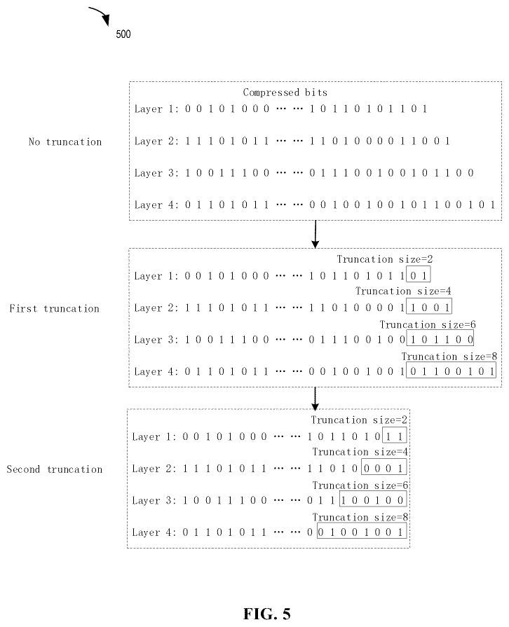

In the following, how to truncate the compressed bits will be discussed in detail. Further, in order to better understand the following embodiments, reference is now made to FIGS. 3A and 3B, which illustrate example blocks of truncating procedures 300A and 300B with respect to a layer.

In FIG. 3A, as for a layer, the first device 110 may truncate the corresponding compressed bits based on a truncation size (or length). In FIG. 3A, the truncation size for the first truncation is 4 (given for illustrative purpose only), and thus the last 4 bits from the right to the left have been truncated. Further, the truncation size for the second truncation is 4 (given for illustrative purpose only, also may be a value rather then 4), and thus the last 4 bits from the right to the left have been truncated from the remaining compressed bits. In other words, the compressed bits need to be truncated gradually by a truncation size.

The truncating procedure 300A is more flexible and is more suitable for the scenario where one encoder corresponds to a large number of decoders. Further, by introducing (or specifying) a reasonable truncation size, it may be guaranteed that the truncated compressed bits may still be mapped (or dequantized) to a complete latent space (i.e., floating sequence).

In FIG. 3B, as for a layer, the first device 110 may truncate the corresponding compressed bits to (compressed bits with) an effective length of compressed bits, or the first device 110 may keep/retain the compressed bits with an effective length.

Given for illustrative purpose only, in FIG. 3B, the set of effective lengths is {60, 30, . . . }, and the total number of compressed bits to truncated is 80. As illustrated in FIG. 3B, as for the first truncation, the first 60 compressed bits from the left to the right is kept, and thus the last 20 bits from the right to the left have been truncated. Further, as for the second truncation, the first 30 compressed bits from the left to the right is kept, and thus the last 30 bits from the right to the left have been truncated from the 60 remaining compressed bits.

The truncating procedure 300B is simpler and more suitable for the scenario where one encoder corresponds to a few decoders.

The truncating procedures 300A and 300B may achieve a similar result, i.e., truncating to compressed bits to an expectable size.

In some embodiments of the present disclosure, for each truncating operation, compressed bits corresponding each layer are truncated. The truncating operation may be performed based on either the truncation size information or the effective length information, which will be discussed separately below.

In some embodiments, the first device 110 may iteratively truncate the compressed bits until the first condition is met. Further, for each truncating operation, compressed bits corresponding each layer are truncated based on one of the following: a respective truncation size, or a truncation size comprised in a set of truncation sizes.

In some embodiments, the truncation sizes for different layers may be the same. That is, the compressed bits corresponding to all layers are truncated simultaneously and gradually by a same truncation size, where the truncation size indicates the size (or length) of truncated bits (at a time). The value of the truncation size may be an integer that is larger than 0, and the unit of the truncation size is bit.

Merely for a better understanding, reference is now made to FIG. 4, which illustrates an example block of truncating procedure 400. In FIG. 4, the truncation size is 4. For each layer, the corresponding compressed bits are truncated gradually by 4 bits, i.e., for the first truncation, the compressed bits are truncated by 4 bits, for the second truncation, the compressed bits are also truncated by 4 bits, and the compressed bits are iteratively truncated until the first condition is met.

Alternatively, in some embodiments, the truncation sizes for different layers may be different. That is, the compressed bits corresponding to all layers are truncated simultaneously by separate truncation sizes. Specifically, each layer may correspond to a truncation size and an optionally truncation step size. Merely for a better understanding, reference is now made to FIG. 5, which illustrates an example block of truncating procedure 500. In FIG. 5, the truncation sizes corresponding to layer 1~4 are 2, 4, 6 and 8, respectively.

In some embodiments, truncation sizes for different truncating operations may be the same.

Alternatively, in some embodiments, truncation sizes for different truncating operations may be different. That is, the truncation size for each truncation may different. In this event, the truncation size may be also determined based on a truncation step size, where the truncation step size indicates a difference between two adjacent truncation sizes. The value of the truncation size may be an integer that is larger than, less than or equal to 0, and the unit of the truncation step size is bit.

In some embodiments, truncation step sizes for different layers may be the same. Alternatively, in some embodiments, truncation step sizes for different layers may be different.

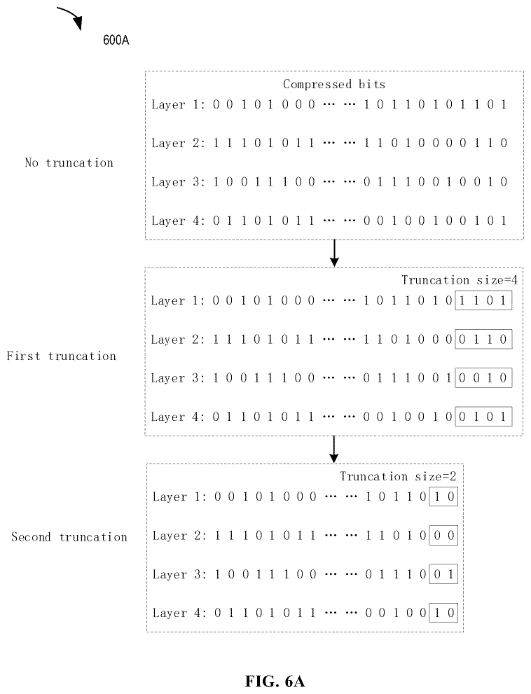

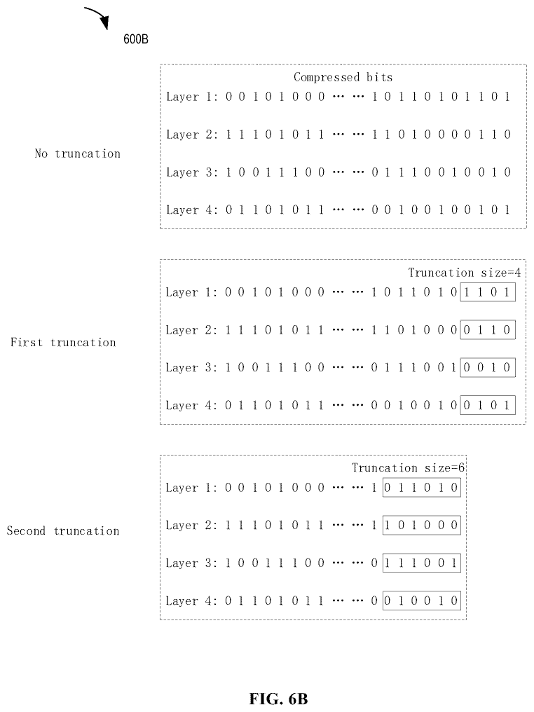

Merely for a better understanding, reference is now made to FIG. 6A and FIG. 6B, which illustrate example blocks of truncating procedure 600A and 600B. In FIG. 6A, the truncation size is 4, and the truncation step size is −2. In FIG. 6B, the truncation size is 4, and the truncation step size is 2.

In some embodiments, truncation step sizes for different truncating operations may be the same. Alternatively, in some embodiments, truncation step sizes for different truncating operations may be different.

In addition to the truncation size information, the iteratively truncating also may be performed based on the effective length information as discussed below.

In some embodiments, the compressed bits corresponding to all layers are truncated simultaneously (and gradually) to a same effective length of compressed bits, or separate effective lengths.

In some embodiments, the first device 110 may iteratively truncate the compressed bits until the first condition is met. Further, for each truncating operation, compressed bits corresponding each layer are truncated based on one of the following: a respective effective length, or an effective length comprised in a set of effective lengths.

In some embodiments, effective lengths for different layers may be the same.

Alternatively, in some embodiments, effective lengths for different layers may be different.

In some embodiments, effective lengths for different truncating operations may be the same.

Alternatively, in some embodiments, effective lengths for different truncating operations may be different.

In some embodiments, the effective length may be determined based on a set of effective lengths. Further, the first device 110 may be provided with one or multiple sets of effective lengths for multiple layers. If multiple sets are provided, each layer will correspond to a set of effective lengths. Further, the set of effective lengths may be determined based on at least one of the following: may be provided by the second device 120 by using an RRC signaling, a MAC CE or DCI, or may be determined based on a set of information, such as, a set of model information, a set of quantization information, a set of CSI payload information and so on.

As discussed above, priorities of different layers may be different. In view of this, in some embodiments, the first device 110 may truncate the compressed bits layer by layer according to a priority of layer.

In some embodiments, the compressed bits corresponding to layers may be truncated according to a priority order about layer (or priority of layer). Specifically, each layer may correspond to a priority. The compressed bits corresponding to the layer with lower priority will be truncated first. That is, the compressed bits corresponding to the layer with the lowest priority will firstly be truncated, and the compressed bits corresponding to the layer with the highest priority will eventually be truncated.

In some other embodiments, it is also possible that the compressed bits corresponding to the layer with higher priority may be truncated first. Additionally, the compressed bits corresponding to multiple layers with the same priority may be truncated simultaneously.

In some embodiments, the first device 110 may continuously truncate compressed bits corresponding to a layer of the plurality of layers until a second condition for stopping truncating compressed bits corresponding to the layer is met, as discussed below.

In some embodiments, the first device 110 may truncate compressed bits corresponding to the plurality of layers in a manner of polling among the plurality of layers.

Assuming that the priorities of Layer 1~Layer 4 from high to low are: Layer 1>Layer 2>Layer 3>Layer 4, the first device 110 may start to truncate the corresponding compressed bits from the layer with the lowest priority (i.e., Layer 4).

In some embodiments, after completing the first truncation, the first device 110 may determine whether the second condition is satisfied for Layer 4. If not satisfied, the first device 110 may continue to truncate the compressed bits corresponding to Layer 4.

If the second condition is satisfied for Layer 4, the first device 110 may start to truncate compressed bits to next layer (i.e., Layer 3).

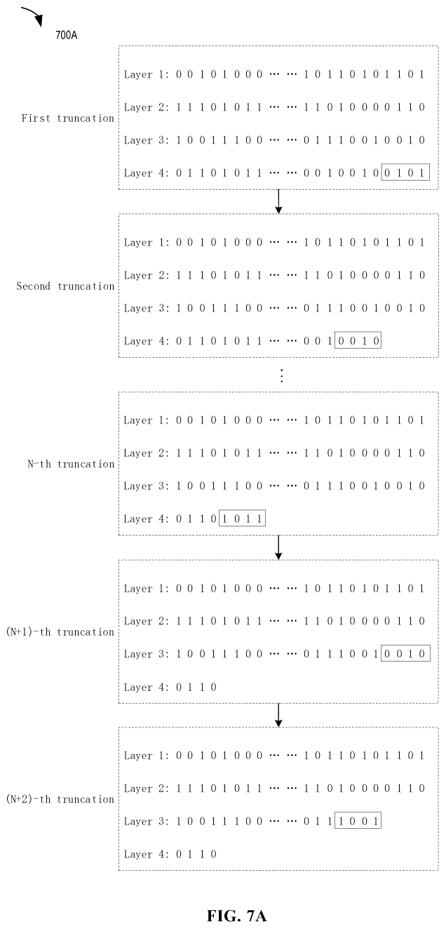

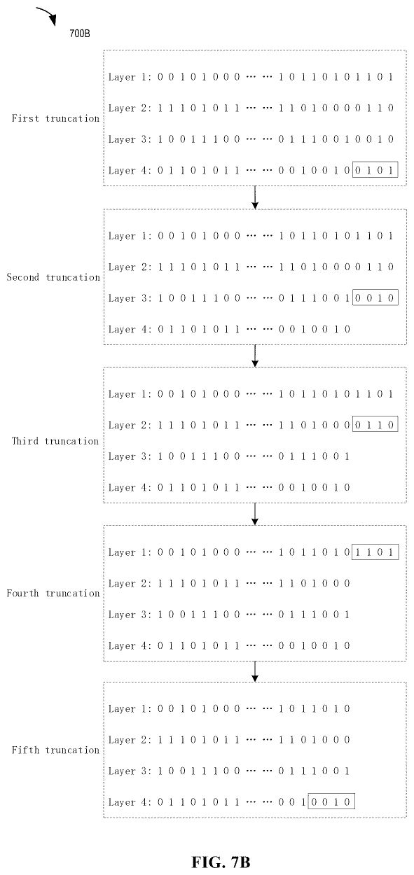

Merely for a better understanding, reference is now made to FIG. 7A, which illustrates an example block of truncating procedure 700A.

In FIG. 7A, assuming that the truncation size (corresponding to) each layer is 4, and the truncation step size is 0. The second condition is that the allowed smallest length of compressed bits is 4.

In FIG. 7A, for the first truncation, the compressed bits corresponding to Layer 4 are truncated by 4 bits. After the first truncation, the second condition is not satisfied, i.e., the length of the remaining compressed bits is larger than 4.

For the second truncation, the compressed bits corresponding to Layer 4 continue to be truncated by 4 bits. For the N-th truncation, the compressed bits corresponding to Layer 4 continue to be truncated by 4 bits. After the N-th truncation, the length of the remaining compressed bits is 4. Thereby, the second condition is satisfied. In this event, for (N+1)-th truncation, the compressed bits corresponding to Layer 3 are truncated by 4 bits.

In some embodiments, assuming that the priorities of Layer 1~Layer 4 from high to low are: Layer 1>Layer 2>Layer 3>Layer 4, the first device 110 may start to truncate the corresponding compressed bits from the layer with the lowest priority (i.e., Layer 4).

After completing the first truncation, the first device 110 may start to truncate compressed bits to next layer (i.e., Layer 3). After this truncation, the first device 110 may start to truncate compressed bits to next layer (i.e., Layer 2). After this truncation, the first device 110 may start to truncate compressed bits to next layer (i.e., Layer 1). After this truncation, the first device 110 may start to truncate compressed bits to next layer (i.e., Layer 4).

Merely for a better understanding, reference is now made to FIG. 7B, which illustrates an example block of truncating procedure 700B.

In FIG. 7B, for the first truncation, the compressed bits corresponding to Layer 4 are truncated by 4 bits. For the second truncation, the compressed bits corresponding to Layer 3 are truncated by 4 bits. For the third truncation, the compressed bits corresponding to Layer 2 are truncated by 4 bits. For the fourth truncation, the compressed bits corresponding to Layer 1 are truncated by 4 bits. For the fifth truncation, the compressed bits corresponding to Layer 4 are truncated by 4 bits. Before the truncation for each layer, UE needs to determine whether Condition 2 is satisfied for the layer. If satisfied, the layer will be omitted and next layer will be processed. If not satisfied, the truncation for the layer will be performed.

In some embodiments, the compressed bits corresponding to layers can be truncated according to priority of layer. Specifically, the compressed bits corresponding to the layer with lower priority will be truncated first to an EL.

The above example embodiments discussed with reference to truncation size information also suitable for the scenario of effective length information by replacing truncation size with EL. For brevity, the same or similar contents are omitted herein.

In some embodiments, the first device 110 may determine the total number of compressed bits to be truncated based on available resources configured for transmitting compressed bits and the total number of compressed bits of the plurality of layers, and further determine the number of compressed bits to be truncated for a layer of the plurality of layers based on the total number of compressed bits to be truncated and at least one of the following:
the number of layers,
a priority of layer,
the number of compressed bits corresponding to the layer,
the total number of compressed bits corresponding to the plurality of layers,
a maximum truncation size corresponding to the layer,
a common maximum truncation size corresponding to more than one layers,
a minimum allowed number of compressed bits corresponding to the layer, or
a common minimum allowed number of compressed bits corresponding to more than one layer.

In some embodiments, the first device 110 only needs to truncate the compressed bits at only once. Specifically, the truncation size may be determined based on a total truncation size, where the total truncation size can be determined based on at least one of resources required for compressed bits, or available resources for compressed bits.

For example, the total truncation size can be determined based on the difference between the resources required for compressed bits and the available resources for compressed bits, e.g.,

$$Total truncation size = ⌈ ( {O}_{CSI - 2} + {L}_{CSI - 2} ) \cdot {β}_{offset}^{PUSCH} \cdot {\sum }_{i = 0}^{{N}_{symb , all}^{PUSCH} - 1} {M}_{sc}^{UCI} ( l ) / {\sum }_{i = 0}^{{C}_{UL - SCH} - 1} {K}_{r} ⌉ \leq ⌈ α \cdot {\sum }_{i = 0}^{{N}_{symb , all}^{PUSCH} - 1} {M}_{sc}^{UCI} ( l ) ⌉ - {Q}_{ACK / CG - UCI}^{′} - {Q}_{CSI - 1}^{′} .$$

After determining the total truncation size, the first device 110 may determine the truncation size corresponding to a layer as discussed below.

In some embodiments, the truncation size corresponding to a layer may be determined based on at least one of the total truncation size or the number of layers, e.g., Second truncation size=┌First truncation size/the number of layers┐, where “┌ ┐” refers to round up to an integer.

In some embodiments, the truncation size corresponding to a layer may be determined based on at least one of the total truncation size or a set of truncation sizes corresponding to the layer.

In some embodiments, the set of truncation sizes may be provided by the second device 120. Optionally, the set of truncation sizes may be determined based on a set of information, such as, a set of model information, a set of quantization information, a set of CSI payload information and so on.

Specifically, for each layer, the first device 110 may determine a minimum truncation size from the set of truncation sizes as the (target) truncation size corresponding to the layer, and the sum of the truncation sizes corresponding to all layers needs to be less than or equal to the total truncation size.

In some embodiments, the truncation size corresponding to a layer may be determined based on at least one of the total truncation size or the priority of layer. Assuming that the priorities of Layer 1~Layer 4 from high to low are: Layer 1>Layer 2>Layer 3>Layer 4, the total truncation size is 60, the length of compressed bits corresponding to both Layer 4 and Layer 3 is 120 bits, the truncation method may be implemented as below.

The compressed bits corresponding to Layer 4 is prioritized to be truncated, and the corresponding truncation size is 60. The truncation size corresponding to Layer 3/2/1 is 0. For another example, assuming the smallest size of compressed bits corresponding to Layer 4 is 100, the smallest size of compressed bits corresponding to Layer 3 is 60. In this event, the truncation size corresponding to Layer 4 is 20. The truncation size corresponding to Layer 3 is 40. The truncation size corresponding to Layer 2/1 is 0.

In some embodiments, the truncation size corresponding to a layer may be determined based on at least one of the total truncation size, the length of compressed bits corresponding to the layer and the sum of lengths of compressed bits corresponding to all layers, e.g., based on the weight of the length of compressed bits corresponding to the layer.

In some embodiments, the plurality of layers are corresponding to a plurality of sets of effective lengths, and the first device 110 may determine an effective length from a respective set of effective lengths for each layer, such that:
a sum value of a plurality of effective lengths corresponding to the plurality of layers meets requirements of available resources configured for transmitting compressed bits;
the sum value of the plurality of effective lengths is maximized; or
effective lengths for different layers correspond to a same effective length identifier.

In some embodiments, the first device 110 may determine an effective length from the set of effective lengths based on some conditions. In other words, the determined effective lengths need to satisfy at least one the following conditions:
The sum of determined effective lengths corresponding to all layers (i.e., size of CSI part 2 comprising the truncated bits corresponding to all layers obtained based on the determined ELs) needs to satisfy the first condition, e.g.,

$$⌈ ( Sum of all ELs + {L}_{CSI - 2} ) \cdot {β}_{offset}^{PUSCH} \cdot {\sum }_{i = 0}^{{N}_{symb , all}^{PUSCH} - 1} {M}_{sc}^{UCI} ( l ) / {\sum }_{i = 0}^{{C}_{UL - SCH} - 1} {K}_{r} ⌉ \leq ⌈ α \cdot {\sum }_{i = 0}^{{N}_{symb , all}^{PUSCH} - 1} {M}_{sc}^{UCI} ( l ) ⌉ - {Q}_{ACK / CG - UCI}^{′} - {Q}_{CSI - 1}^{′} .$$

In some embodiments, the identifier of determined effective length corresponding to each layer are the same. Maybe multiple set of effective lengths corresponding to multiple layers may have the same number of effective lengths.

In some embodiments, the determined effective length(s) needs to be as large as possible. For example, the sum of determined effective lengths corresponding to all layers needs to make the value of left part as close as possible to the value of right part.

Furthermore, when determining the truncation size(s), in addition to the needed information, the truncation size may also be determined based on the smallest size of compressed bits (or largest truncation size) corresponding to the layer.

In some embodiments, if the second condition is satisfied for each layer, or the third condition is satisfied, the first device 110 may omit (all) compressed bits corresponding to a layer based on priorities of the layers.

In some embodiments, the first device 110 may omit remaining compressed bits corresponding to the plurality of layers layer by layer according to a priority of layer if: the total number of remaining compressed bits corresponding to each of the plurality of layers satisfies a second condition for stopping truncating compressed bits corresponding to the layer; and the total number of remaining compressed bits corresponding to the plurality of layers meets a third condition.

In some embodiments, for model/performance monitoring for a group of decoders (or models), the first device 110 may only need to monitor one specific decoder out of the group of decoders.

In some embodiments, the first device 110 may determine, a model from a plurality of models deployed at a second device 120 based on at least one of the following:

a plurality of respective numbers of compressed bits corresponding to the plurality of models, or a plurality of respective model identifiers corresponding to the plurality of models. Then the first device 110 may monitor the model determined from the plurality of models deployed at the second device 120.

In some embodiments, the first device 110 may determine the specific decoder based on the following: the specific decoder corresponds to the largest or smallest size of compressed bits, or the specific decoder corresponds to the largest or lowest identifier of decoder. That is, the determined model may be one of the following:
a model corresponding to the maximum number of compressed bits,
a model corresponding to the minimum number of compressed bits,
a model corresponding to the maximum model identifier, or
a model corresponding to the minimum model identifier.

In this way, the power consumption at the first device 110 may be saved accordingly.

### Example Methods

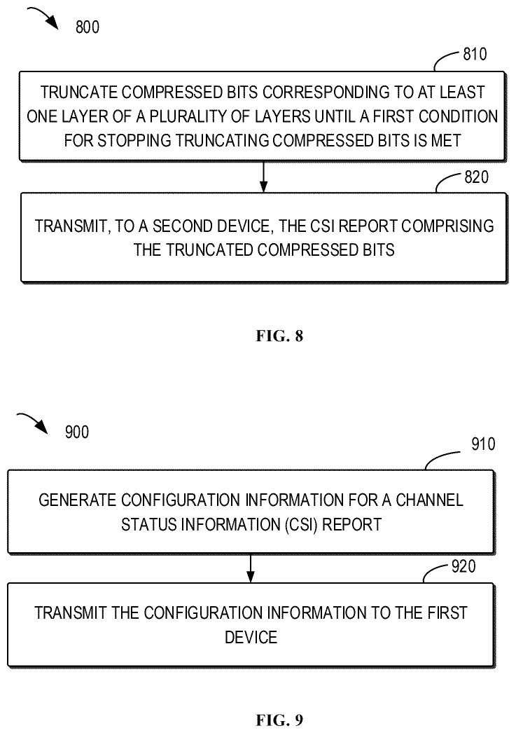

FIG. 8 illustrates a flowchart of a communication method 800 implemented at a first device in accordance with some embodiments of the present disclosure. For the purpose of discussion, the method 800 will be described from the perspective of first device 110 in FIG. 1A.

At block 810, first device truncates compressed bits corresponding to at least one layer of a plurality of layers until a first condition for stopping truncating compressed bits is met and based at least in part on at least one of the following: truncation size information, indicating the number of compressed bits corresponding to the plurality of layers truncated during the truncating, or effective length information, indicating the number of remaining compressed bits corresponding to the plurality of layers during the truncating.

At block 820, first device transmits, to a second device, the CSI report comprising the truncated compressed bits.

In some example embodiments, the truncation size information comprises at least one of the following: a truncation size, indicating the number of compressed bits truncated from compressed bits corresponding to a layer of the plurality of layers for each truncating operation, wherein the truncation size is either a common size configured for the plurality of layers or a specific size configured for one of the plurality of layers, a truncation step size, indicating a difference of truncation sizes of two consecutive truncating operations, wherein the truncation step size is either a common size configured for the plurality of layers or a specific size configured for one of the plurality of layers, or a set of truncation sizes, indicating a set of allowed truncation sizes for a layer, wherein the set of truncation sizes is either a common set configured for the plurality of layers or a specific set configured for one of the plurality of layers; and wherein the effective length information comprises at least one of the following: an effective length, indicating the number of allowed remaining compressed bits for a layer of the plurality of layers, wherein the effective length is either a common effective length configured for the plurality of layers or a specific effective length configured for one of the plurality of layers, or a set of effective lengths, indicating a set of numbers of allowed remaining compressed bits for a layer of the plurality of layers, wherein the set of effective lengths is either a common set configured for the plurality of layers or a specific set configured for one of the plurality of layers.

In some example embodiments, the first device may iteratively truncate the compressed bits until the first condition is met, and wherein for each truncating operation, compressed bits corresponding each layer are truncated based on one of the following: a respective truncation size, a truncation size comprised in a set of truncation sizes, a respective effective length, or an effective length comprised in a set of effective lengths.

In some example embodiments, truncation sizes for different layers are the same or different, truncation sizes for different truncating operations are the same or different, truncation step sizes for different layers are the same or different, truncation step sizes for different truncating operations are the same or different, effective lengths for different layers are the same or different, or effective lengths for different truncating operations are the same or different.

In some example embodiments, the first device may truncate the compressed bits layer by layer according to a priority of layer by performing one of the following:

continuously truncating compressed bits corresponding to a layer of the plurality of layers until a second condition for stopping truncating compressed bits corresponding to the layer is met, or truncating compressed bits corresponding to the plurality of layers in a manner of polling among the plurality of layers.

In some example embodiments, the first device may determine the total number of compressed bits to be truncated based on available resources configured for transmitting compressed bits and the total number of compressed bits of the plurality of layers; and may determine the number of compressed bits to be truncated for a layer of the plurality of layers based on the total number of compressed bits to be truncated and at least one of the following: the number of layers, a priority of layer, the number of compressed bits corresponding to the layer, the total number of compressed bits corresponding to the plurality of layers, a maximum truncation size corresponding to the layer, a common maximum truncation size corresponding to more than one layers, a minimum allowed number of compressed bits corresponding to the layer, or a common minimum allowed number of compressed bits corresponding to more than one layer.

In some example embodiments, the plurality of layers are corresponding to a plurality of sets of effective lengths, and the first device may determine an effective length from a respective set of effective lengths for each layer, such that: a sum value of a plurality of effective lengths corresponding to the plurality of layers meets requirements of available resources configured for transmitting compressed bits; the sum value of the plurality of effective lengths is maximized; or effective lengths for different layers correspond to a same effective length identifier.

In some example embodiments, the first device may omit remaining compressed bits corresponding to the plurality of layers layer by layer according to a priority of layer if: the total number of remaining compressed bits corresponding to each of the plurality of layers satisfies a second condition for stopping truncating compressed bits corresponding to the layer; and the total number of remaining compressed bits corresponding to the plurality of layers meets a third condition.

In some example embodiments, the first device may determine the first condition is met in response to at least one of the following: the total number of remaining compressed bits corresponding to the plurality of layers satisfies the requirements of available resources for transmitting compressed bits, or for each of the plurality of layers, the number of remaining compressed bits meets a second condition for stopping truncating compressed bits corresponding to a layer.

In some example embodiments, the first device may determine a second condition for stopping truncating compressed bits corresponding to a layer is met in response to at least one of the following: all compressed bits corresponding to the layer have been truncated, or the number of remaining compressed bits corresponding to the layer is equal to or smaller than a threshold number.

In some example embodiments, any of the truncation size information and the effective length information is determined based on at least one of the following: a rank indicator, an index of a layer, parity of an index of a layer, the number of compressed bits corresponding to a layer, a truncation ratio, model-related information associated with a layer, quantization-related information associated with a layer, or CSI payload information associated with a layer.

In some example embodiments, a priority of a layer of the plurality of layers is determined based on at least one of the following: an index of a layer, parity of an index of a layer, quality of a layer, the number of compressed bits corresponding to a layer, model-related information associated with a layer, quantization information associated with a layer, or CSI payload information associated with a layer.

In some example embodiments, the model-related information comprises at least one of the following: an identity of a model, model description information, data information corresponding to a mode, performance of a model, a configuration associated with a model, a scenario associated with a model a site associated with a model, or a cell associated with a model.

In some example embodiments, the quantization-related information comprises at least one of the following: an identity of a quantization, a type of quantization, a size of segment for vector quantization, the number of segments for vector quantization, information related to a codebook of quantization for vector quantization, the number of quantization bits, the number of quantization bits per segment for vector quantization, a quantization granularity, or performance of quantization.

In some example embodiments, the CSI payload information comprises at least one of the following: an indication indicating a CSI payload size, an indication indicating a size of compressed bits, an indication indicating a size of second part of a CSI report, or an indication indicating a compression ratio.

In some example embodiments, the first device may receive from the second device, configuration information for a channel status information (CSI) report, the configuration information indicating at least one of the following: an indication used for enabling or disabling truncating the compressed bits corresponding to the plurality of layers, the truncation size information, or the effective length information.

In some example embodiments, the configuration information is comprised in at least one of the following: a radio resource control (RRC) signalling, a medium access control (MAC) control element (CE), or downlink control information (DCI).

In some example embodiments, the first device may transmit capability-related information of the first device to the second device, the capability-related information indicating at least one of the following: a first capability indicating whether the first device supports truncating the compressed bits, a second capability indicates the maximum or minimum value of a truncation size supported by the first device, a third capability indicates the maximum or minimum value of a truncation step size supported by the first device, or a fourth capability indicates the maximum or minimum value of an effective length supported by the first device.

In some example embodiments, a first part of the CSI report comprises at least one of the following: information about whether the truncating is performed, information about identifier of one or more truncated layers, information about the number of times truncating operations, information about a truncation size used by the first device, information about a truncation step size used by the first device, or information about an effective length used by the first device.

In some example embodiments, the first device may truncate the compressed bits according to an order of from right to left or from the least significant bit (LSB) to the most significant bit (MSB).

In some example embodiments, the first device is a terminal device and the second device is a network device.

FIG. 9 illustrates a flowchart of a communication method 900 implemented at a second device in accordance with some embodiments of the present disclosure. For the purpose of discussion, the method 900 will be described from the perspective of the second device 120 in FIG. 1A.

At block 910, the second device generates configuration information for a channel status information (CSI) report, the configuration information indicating at least one of the following: an indication used for enabling or disabling truncating compressed bits corresponding to the plurality of layers, truncation size information, indicating the number of compressed bits corresponding to a plurality of layers truncated during the truncating, or effective length information, indicating the number of remaining compressed bits corresponding to the plurality of layers during the truncating.

At block 920, the second device transmits the configuration information to the first device.

In some example embodiments, the truncation size information comprises at least one of the following: a truncation size, indicating the number of compressed bits truncated from compressed bits corresponding to a layer of the plurality of layers for each truncating operation, wherein the truncation size is either a common size configured for the plurality of layers or a specific size configured for one of the plurality of layers, a truncation step size, indicating a difference of truncation sizes of two consecutive truncating operations, wherein the truncation step size is either a common size configured for the plurality of layers or a specific size configured for one of the plurality of layers, or a set of truncation sizes, indicating a set of allowed truncation sizes for a layer, wherein the set of truncation sizes is either a common set configured for the plurality of layers or a specific set configured for one of the plurality of layers; and wherein the effective length information comprises at least one of the following: an effective length, indicating the number of allowed remaining compressed bits for a layer of the plurality of layers, wherein the effective length is either a common effective length configured for the plurality of layers or a specific effective length configured for one of the plurality of layers, or a set of effective lengths, indicating a set of numbers of allowed remaining compressed bits for a layer of the plurality of layers, wherein the set of effective lengths is either a common set configured for the plurality of layers or a specific set configured for one of the plurality of layers.

In some example embodiments, any of the truncation size information and the effective length information is determined based on at least one of the following: a rank indicator, an index of a layer, parity of an index of a layer, the number of compressed bits corresponding to a layer, a truncation ratio, model-related information associated with a layer, quantization-related information associated with a layer, or CSI payload information associated with a layer.

In some example embodiments, a priority of a layer of the plurality of layers is determined based on at least one of the following: an index of a layer, parity of an index of a layer, quality of a layer, the number of compressed bits corresponding to a layer, model-related information associated with a layer, quantization information associated with a layer, or CSI payload information associated with a layer.

In some example embodiments, the model-related information comprises at least one of the following: an identity of a model, model description information, data information corresponding to a mode, performance of a model, a configuration associated with a model, a scenario associated with a model, a site associated with a model, or a cell associated with a model.

In some example embodiments, the quantization-related information comprises at least one of the following: an identity of a quantization, a type of quantization, a size of segment for vector quantization, the number of segments for vector quantization, information related to a codebook of quantization for vector quantization, the number of quantization bits, the number of quantization bits per segment for vector quantization, a quantization granularity, or performance of quantization.

In some example embodiments, the CSI payload information comprises at least one of the following: an indication indicating a CSI payload size, an indication indicating a size of compressed bits, an indication indicating a size of second part of a CSI report, or an indication indicating a compression ratio.

In some example embodiments, the configuration information is comprised in at least one of the following: a radio resource control (RRC) signalling, a medium access control (MAC) control element (CE), or downlink control information (DCI).

In some example embodiments, a first part of the CSI report comprises at least one of the following: information about whether the truncating is performed, information about identifier of one or more truncated layers, information about the number of times truncating operations, information about a truncation size used by the first device, information about a truncation step size used by the first device, or information about an effective length used by the first device.

In some example embodiments, the second device the second device may receive, from the first device, capability-related information of the first device, the capability-related information indicating at least one of the following: a first capability indicating whether the first device supports truncating the compressed bits, a second capability indicates the maximum or minimum value of a truncation size supported by the first device, a third capability indicates the maximum or minimum value of a truncation step size supported by the first device, or a fourth capability indicates the maximum or minimum value of an effective length supported by the first device.

In some example embodiments, the first device is a terminal device and the second device is a network device.

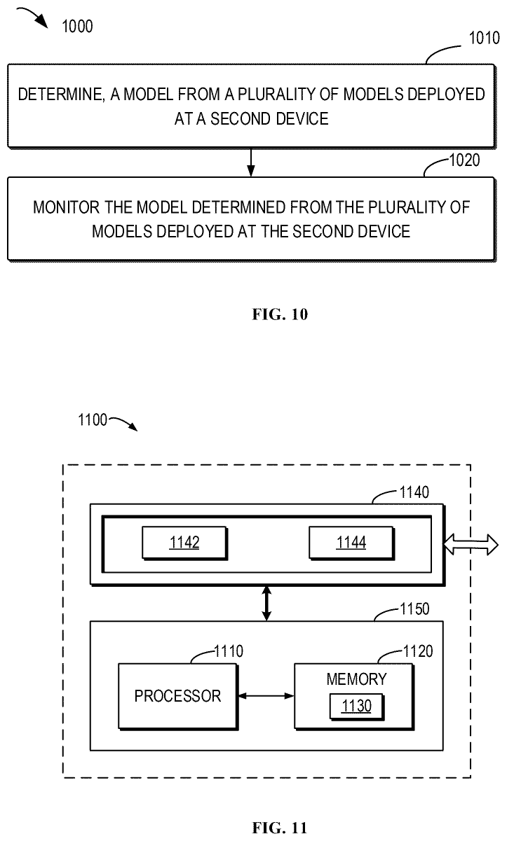

FIG. 10 illustrates a flowchart of a communication method 1000 implemented at a first device in accordance with some embodiments of the present disclosure. For the purpose of discussion, the method 1000 will be described from the perspective of the first device 110 in FIG. 1A.

At block 1010, the first device determines, a model from a plurality of models deployed at a second device based on at least one of the following: a plurality of respective numbers of compressed bits corresponding to the plurality of models, or a plurality of respective model identifiers corresponding to the plurality of models.

At block 1040, the first device monitors the model determined from the plurality of models deployed at the second device.

In some example embodiments, the model is one of the following: a model corresponding to the maximum number of compressed bits, a model corresponding to the minimum number of compressed bits, a model corresponding to the maximum model identifier, or a model corresponding to the minimum model identifier.

In some example embodiments, the first device is a terminal device and the second device is a network device.

### Example Devices and Apparatuses

FIG. 11 is a simplified block diagram of a device 1100 that is suitable for implementing embodiments of the present disclosure. The device 1100 can be considered as a further example implementation of any of the devices as shown in FIG. 1A.

Accordingly, the device 1100 can be implemented at or as at least a part of the first device 110 or the second device 120.

As shown, the device 1100 includes a processor 1110, a memory 1120 coupled to the processor 1110, a suitable transceiver 1140 coupled to the processor 1110, and a communication interface coupled to the transceiver 1140. The memory 1110 stores at least a part of a program 1130. The transceiver 1140 may be for bidirectional communications or a unidirectional communication based on requirements. The transceiver 1140 may include at least one of a transmitter 1142 and a receiver 1144. The transmitter 1142 and the receiver 1144 may be functional modules or physical entities. The transceiver 1140 has at least one antenna to facilitate communication, though in practice an Access Node mentioned in this application may have several ones. The communication interface may represent any interface that is necessary for communication with other network elements, such as X2/Xn interface for bidirectional communications between eNBs/gNBs, S1/NG interface for communication between a Mobility Management Entity (MME)/Access and Mobility Management Function (AMF)/SGW/UPF and the eNB/gNB, Un interface for communication between the eNB/gNB and a relay node (RN), or Uu interface for communication between the eNB/gNB and a terminal device.

The program 1130 is assumed to include program instructions that, when executed by the associated processor 1110, enable the device 1100 to operate in accordance with the embodiments of the present disclosure, as discussed herein with reference to FIGS. 1 to 11. The embodiments herein may be implemented by computer software executable by the processor 1110 of the device 1100, or by hardware, or by a combination of software and hardware. The processor 1110 may be configured to implement various embodiments of the present disclosure. Furthermore, a combination of the processor 1110 and memory 1120 may form processing means 1150 adapted to implement various embodiments of the present disclosure.

The memory 1120 may be of any type suitable to the local technical network and may be implemented using any suitable data storage technology, such as a non-transitory computer readable storage medium, semiconductor based memory devices, magnetic memory devices and systems, optical memory devices and systems, fixed memory and removable memory, as non-limiting examples. While only one memory 1120 is shown in the device 1100, there may be several physically distinct memory modules in the device 1100. The processor 1110 may be of any type suitable to the local technical network, and may include one or more of general purpose computers, special purpose computers, microprocessors, digital signal processors (DSPs) and processors based on multicore processor architecture, as non-limiting examples. The device 1100 may have multiple processors, such as an application specific integrated circuit chip that is slaved in time to a clock which synchronizes the main processor.

According to embodiments of the present disclosure, a first device comprising a circuitry is provided. The circuitry is configured to: truncate compressed bits corresponding to at least one layer of a plurality of layers until a first condition for stopping truncating compressed bits is met and based at least in part on at least one of the following: truncation size information, indicating the number of compressed bits corresponding to the plurality of layers truncated during the truncating, or effective length information, indicating the number of remaining compressed bits corresponding to the plurality of layers during the truncating; transmit, to a second device, the CSI report comprising the truncated compressed bits. According to embodiments of the present disclosure, the circuitry may be configured to perform any method implemented by the first device as discussed above.

According to embodiments of the present disclosure, a second device comprising a circuitry is provided. The circuitry is configured to: generate configuration information for a channel status information (CSI) report, the configuration information indicating at least one of the following: an indication used for enabling or disabling truncating compressed bits corresponding to the plurality of layers, truncation size information, indicating the number of compressed bits corresponding to a plurality of layers truncated during the truncating, or effective length information, indicating the number of remaining compressed bits corresponding to the plurality of layers during the truncating; and transmit the configuration information to the first device. According to embodiments of the present disclosure, the circuitry may be configured to perform any method implemented by the second device as discussed above.

According to embodiments of the present disclosure, a first device comprising a circuitry is provided. The circuitry is configured to: determine, a model from a plurality of models deployed at a second device based on at least one of the following: a plurality of respective numbers of compressed bits corresponding to the plurality of models, or a plurality of respective model identifiers corresponding to the plurality of models; and monitor the model determined from the plurality of models deployed at the second device. According to embodiments of the present disclosure, the circuitry may be configured to perform any method implemented by the first device as discussed above.

The term “circuitry” used herein may refer to hardware circuits and/or combinations of hardware circuits and software. For example, the circuitry may be a combination of analog and/or digital hardware circuits with software/firmware. As a further example, the circuitry may be any portions of hardware processors with software including digital signal processor(s), software, and memory(ies) that work together to cause an apparatus, such as a terminal device or a network device, to perform various functions. In a still further example, the circuitry may be hardware circuits and or processors, such as a microprocessor or a portion of a microprocessor, that requires software/firmware for operation, but the software may not be present when it is not needed for operation. As used herein, the term circuitry also covers an implementation of merely a hardware circuit or processor(s) or a portion of a hardware circuit or processor(s) and its (or their) accompanying software and/or firmware.

According to embodiments of the present disclosure, a first apparatus is provided. The first apparatus comprises means for truncating compressed bits corresponding to at least one layer of a plurality of layers until a first condition for stopping truncating compressed bits is met and based at least in part on at least one of the following: means for truncation size information, indicating the number of compressed bits corresponding to the plurality of layers truncated during the truncating, or means for effective length information, indicating the number of remaining compressed bits corresponding to the plurality of layers during the truncating; means for transmitting, to a second device, the CSI report comprising the truncated compressed bits.

In some embodiments, the first apparatus may comprise means for performing the respective operations of the method 800.

In some example embodiments, the first apparatus may further comprise means for performing other operations in some example embodiments of the method 800. The means may be implemented in any suitable form. For example, the means may be implemented in a circuitry or software module.

According to embodiments of the present disclosure, a second apparatus is provided. The second apparatus comprises means for generating configuration information for a channel status information (CSI) report, the configuration information indicating at least one of the following: means for an indication used for enabling or disabling truncating compressed bits corresponding to the plurality of layers, means for truncation size information, indicating the number of compressed bits corresponding to a plurality of layers truncated during the truncating, or means for effective length information, indicating the number of remaining compressed bits corresponding to the plurality of layers during the truncating; and means for transmitting the configuration information to the first device.

In some embodiments, the second apparatus may comprise means for performing the respective operations of the method 900.

In some example embodiments, the second apparatus may further comprise means for performing other operations in some example embodiments of the method 900. The means may be implemented in any suitable form. For example, the means may be implemented in a circuitry or software module.

According to embodiments of the present disclosure, a first apparatus is provided. The first apparatus comprises means for determining, a model from a plurality of models deployed at a second device based on at least one of the following: a plurality of respective numbers of compressed bits corresponding to the plurality of models, or a plurality of respective model identifiers corresponding to the plurality of models; and means for monitoring the model determined from the plurality of models deployed at the second device.

In some embodiments, the first apparatus may comprise means for performing the respective operations of the method 1000.

In some example embodiments, the first apparatus may further comprise means for performing other operations in some example embodiments of the method 1000. The means may be implemented in any suitable form. For example, the means may be implemented in a circuitry or software module.

In summary, embodiments of the present disclosure provide the following aspects.

In an aspect, it is proposed a first device comprising: a processor configured to cause the first device to: truncate compressed bits corresponding to at least one layer of a plurality of layers until a first condition for stopping truncating compressed bits is met and based at least in part on at least one of the following: truncation size information, indicating the number of compressed bits corresponding to the plurality of layers truncated during the truncating, or effective length information, indicating the number of remaining compressed bits corresponding to the plurality of layers during the truncating; transmit, to a second device, the CSI report comprising the truncated compressed bits.

In some embodiments, the truncation size information comprises at least one of the following: a truncation size, indicating the number of compressed bits truncated from compressed bits corresponding to a layer of the plurality of layers for each truncating operation, wherein the truncation size is either a common size configured for the plurality of layers or a specific size configured for one of the plurality of layers, a truncation step size, indicating a difference of truncation sizes of two consecutive truncating operations, wherein the truncation step size is either a common size configured for the plurality of layers or a specific size configured for one of the plurality of layers, or a set of truncation sizes, indicating a set of allowed truncation sizes for a layer, wherein the set of truncation sizes is either a common set configured for the plurality of layers or a specific set configured for one of the plurality of layers; and wherein the effective length information comprises at least one of the following: an effective length, indicating the number of allowed remaining compressed bits for a layer of the plurality of layers, wherein the effective length is either a common effective length configured for the plurality of layers or a specific effective length configured for one of the plurality of layers, or a set of effective lengths, indicating a set of numbers of allowed remaining compressed bits for a layer of the plurality of layers, wherein the set of effective lengths is either a common set configured for the plurality of layers or a specific set configured for one of the plurality of layers.

In some embodiments, the processor is further configured to cause the first device to: iteratively truncate the compressed bits until the first condition is met, and wherein for each truncating operation, compressed bits corresponding each layer are truncated based on one of the following: a respective truncation size, a truncation size comprised in a set of truncation sizes, a respective effective length, or an effective length comprised in a set of effective lengths.

In some embodiments, truncation sizes for different layers are the same or different, truncation sizes for different truncating operations are the same or different, truncation step sizes for different layers are the same or different, truncation step sizes for different truncating operations are the same or different, effective lengths for different layers are the same or different, or effective lengths for different truncating operations are the same or different.

In some embodiments, the processor is further configured to cause the first device to: truncate the compressed bits layer by layer according to a priority of layer by performing one of the following: continuously truncating compressed bits corresponding to a layer of the plurality of layers until a second condition for stopping truncating compressed bits corresponding to the layer is met, or truncating compressed bits corresponding to the plurality of layers in a manner of polling among the plurality of layers.

In some embodiments, the processor is further configured to cause the first device to: determine the total number of compressed bits to be truncated based on available resources configured for transmitting compressed bits and the total number of compressed bits of the plurality of layers; and determine the number of compressed bits to be truncated for a layer of the plurality of layers based on the total number of compressed bits to be truncated and at least one of the following: the number of layers, a priority of layer, the number of compressed bits corresponding to the layer, the total number of compressed bits corresponding to the plurality of layers, a maximum truncation size corresponding to the layer, a common maximum truncation size corresponding to more than one layers, a minimum allowed number of compressed bits corresponding to the layer, or a common minimum allowed number of compressed bits corresponding to more than one layer.

In some embodiments, the plurality of layers are corresponding to a plurality of sets of effective lengths, and wherein the processor is further configured to cause the first device to: determine an effective length from a respective set of effective lengths for each layer, such that: a sum value of a plurality of effective lengths corresponding to the plurality of layers meets requirements of available resources configured for transmitting compressed bits; the sum value of the plurality of effective lengths is maximized; or effective lengths for different layers correspond to a same effective length identifier.

In some embodiments, the processor is further configured to cause the first device to: omit remaining compressed bits corresponding to the plurality of layers layer by layer according to a priority of layer if: the total number of remaining compressed bits corresponding to each of the plurality of layers satisfies a second condition for stopping truncating compressed bits corresponding to the layer; and the total number of remaining compressed bits corresponding to the plurality of layers meets a third condition.

In some embodiments, the processor is further configured to cause the first device to: determine the first condition is met in response to at least one of the following: the total number of remaining compressed bits corresponding to the plurality of layers satisfies the requirements of available resources for transmitting compressed bits, or for each of the plurality of layers, the number of remaining compressed bits meets a second condition for stopping truncating compressed bits corresponding to a layer.

In some embodiments, the processor is further configured to cause the first device to: determine a second condition for stopping truncating compressed bits corresponding to a layer is met in response to at least one of the following: all compressed bits corresponding to the layer have been truncated, or the number of remaining compressed bits corresponding to the layer is equal to or smaller than a threshold number.

In some embodiments, any of the truncation size information and the effective length information is determined based on at least one of the following: a rank indicator, an index of a layer, parity of an index of a layer, the number of compressed bits corresponding to a layer, a truncation ratio, model-related information associated with a layer, quantization-related information associated with a layer, or CSI payload information associated with a layer.

In some embodiments, a priority of a layer of the plurality of layers is determined based on at least one of the following: an index of a layer, parity of an index of a layer, quality of a layer, the number of compressed bits corresponding to a layer, model-related information associated with a layer, quantization information associated with a layer, or CSI payload information associated with a layer.

In some embodiments, the model-related information comprises at least one of the following: an identity of a model, model description information, data information corresponding to a mode, performance of a model, a configuration associated with a model, a scenario associated with a model a site associated with a model, or a cell associated with a model.

In some embodiments, the quantization-related information comprises at least one of the following: an identity of a quantization, a type of quantization, a size of segment for vector quantization, the number of segments for vector quantization, information related to a codebook of quantization for vector quantization, the number of quantization bits, the number of quantization bits per segment for vector quantization, a quantization granularity, or performance of quantization.

In some embodiments, the CSI payload information comprises at least one of the following: an indication indicating a CSI payload size, an indication indicating a size of compressed bits, an indication indicating a size of second part of a CSI report, or an indication indicating a compression ratio.

In some embodiments, wherein the processor is further configured to cause the first device to: receive from the second device, configuration information for a channel status information (CSI) report, the configuration information indicating at least one of the following: an indication used for enabling or disabling truncating the compressed bits corresponding to the plurality of layers, the truncation size information, or the effective length information.

In some embodiments, the configuration information is comprised in at least one of the following: a radio resource control (RRC) signalling, a medium access control (MAC) control element (CE), or downlink control information (DCI).

In some embodiments, the processor is further configured to cause the first device to: transmit capability-related information of the first device to the second device, the capability-related information indicating at least one of the following: a first capability indicating whether the first device supports truncating the compressed bits, a second capability indicates the maximum or minimum value of a truncation size supported by the first device, a third capability indicates the maximum or minimum value of a truncation step size supported by the first device, or a fourth capability indicates the maximum or minimum value of an effective length supported by the first device.

In some embodiments, a first part of the CSI report comprises at least one of the following: information about whether the truncating is performed, information about identifier of one or more truncated layers, information about the number of times truncating operations, information about a truncation size used by the first device, information about a truncation step size used by the first device, or information about an effective length used by the first device.

In some embodiments, the processor is further configured to cause the first device to: truncate the compressed bits according to an order of from right to left or from the least significant bit (LSB) to the most significant bit (MSB).

In some embodiments, the first device is a terminal device and the second device is a network device.

In an aspect, it is proposed a second device comprising: a processor configured to cause the second device to: generate configuration information for a channel status information (CSI) report, the configuration information indicating at least one of the following: an indication used for enabling or disabling truncating compressed bits corresponding to the plurality of layers, truncation size information, indicating the number of compressed bits corresponding to a plurality of layers truncated during the truncating, or effective length information, indicating the number of remaining compressed bits corresponding to the plurality of layers during the truncating; and transmit the configuration information to the first device.

In some embodiments, the truncation size information comprises at least one of the following: a truncation size, indicating the number of compressed bits truncated from compressed bits corresponding to a layer of the plurality of layers for each truncating operation, wherein the truncation size is either a common size configured for the plurality of layers or a specific size configured for one of the plurality of layers, a truncation step size, indicating a difference of truncation sizes of two consecutive truncating operations, wherein the truncation step size is either a common size configured for the plurality of layers or a specific size configured for one of the plurality of layers, or a set of truncation sizes, indicating a set of allowed truncation sizes for a layer, wherein the set of truncation sizes is either a common set configured for the plurality of layers or a specific set configured for one of the plurality of layers; and wherein the effective length information comprises at least one of the following: an effective length, indicating the number of allowed remaining compressed bits for a layer of the plurality of layers, wherein the effective length is either a common effective length configured for the plurality of layers or a specific effective length configured for one of the plurality of layers, or a set of effective lengths, indicating a set of numbers of allowed remaining compressed bits for a layer of the plurality of layers, wherein the set of effective lengths is either a common set configured for the plurality of layers or a specific set configured for one of the plurality of layers.

In some embodiments, any of the truncation size information and the effective length information is determined based on at least one of the following: a rank indicator, an index of a layer, parity of an index of a layer, the number of compressed bits corresponding to a layer, a truncation ratio, model-related information associated with a layer, quantization-related information associated with a layer, or CSI payload information associated with a layer.

In some embodiments, a priority of a layer of the plurality of layers is determined based on at least one of the following: an index of a layer, parity of an index of a layer, quality of a layer, the number of compressed bits corresponding to a layer, model-related information associated with a layer, quantization information associated with a layer, or CSI payload information associated with a layer.

In some embodiments, the model-related information comprises at least one of the following: an identity of a model, model description information, data information corresponding to a mode, performance of a model, a configuration associated with a model, a scenario associated with a model, a site associated with a model, or a cell associated with a model.

In some embodiments, the quantization-related information comprises at least one of the following: an identity of a quantization, a type of quantization, a size of segment for vector quantization, the number of segments for vector quantization, information related to a codebook of quantization for vector quantization, the number of quantization bits, the number of quantization bits per segment for vector quantization, a quantization granularity, or performance of quantization.

In some embodiments, the CSI payload information comprises at least one of the following: an indication indicating a CSI payload size, an indication indicating a size of compressed bits, an indication indicating a size of second part of a CSI report, or an indication indicating a compression ratio.

In some embodiments, the configuration information is comprised in at least one of the following: a radio resource control (RRC) signalling, a medium access control (MAC) control element (CE), or downlink control information (DCI).

In some embodiments, a first part of the CSI report comprises at least one of the following: information about whether the truncating is performed, information about identifier of one or more truncated layers, information about the number of times truncating operations, information about a truncation size used by the first device, information about a truncation step size used by the first device, or information about an effective length used by the first device.

In some embodiments, the processor is further configured to cause the second device to: receive, from the first device, capability-related information of the first device, the capability-related information indicating at least one of the following: a first capability indicating whether the first device supports truncating the compressed bits, a second capability indicates the maximum or minimum value of a truncation size supported by the first device, a third capability indicates the maximum or minimum value of a truncation step size supported by the first device, or a fourth capability indicates the maximum or minimum value of an effective length supported by the first device.

In some embodiments, the first device is a terminal device and the second device is a network device.

In an aspect, it is proposed a first device comprising: a processor configured to cause the first device to: determine, a model from a plurality of models deployed at a second device based on at least one of the following: a plurality of respective numbers of compressed bits corresponding to the plurality of models, or a plurality of respective model identifiers corresponding to the plurality of models; and monitor the model determined from the plurality of models deployed at the second device.

In some embodiments, the model is one of the following: a model corresponding to the maximum number of compressed bits, a model corresponding to the minimum number of compressed bits, a model corresponding to the maximum model identifier, or a model corresponding to the minimum model identifier.

In some embodiments, the first device is a terminal device and the second device is a network device.

In an aspect, a first device comprises: at least one processor; and at least one memory coupled to the at least one processor and storing instructions thereon, the instructions, when executed by the at least one processor, causing the device to perform the method implemented by the first device discussed above.

In an aspect, a second device comprises: at least one processor; and at least one memory coupled to the at least one processor and storing instructions thereon, the instructions, when executed by the at least one processor, causing the device to perform the method implemented by the second device discussed above.

In an aspect, a computer readable medium having instructions stored thereon, the instructions, when executed on at least one processor, causing the at least one processor to perform the method implemented by the first device discussed above. In an aspect, a computer readable medium having instructions stored thereon,

the instructions, when executed on at least one processor, causing the at least one processor to perform the method implemented by the second device discussed above.

In an aspect, a computer program comprising instructions, the instructions, when executed on at least one processor, causing the at least one processor to perform the method implemented by the first device discussed above.

In an aspect, a computer program comprising instructions, the instructions, when executed on at least one processor, causing the at least one processor to perform the method implemented by the second device discussed above.

Generally, various embodiments of the present disclosure may be implemented in hardware or special purpose circuits, software, logic or any combination thereof. Some aspects may be implemented in hardware, while other aspects may be implemented in firmware or software which may be executed by a controller, microprocessor or other computing device. While various aspects of embodiments of the present disclosure are illustrated and described as block diagrams, flowcharts, or using some other pictorial representation, it will be appreciated that the blocks, apparatus, systems, techniques or methods described herein may be implemented in, as non-limiting examples, hardware, software, firmware, special purpose circuits or logic, general purpose hardware or controller or other computing devices, or some combination thereof.

The present disclosure also provides at least one computer program product tangibly stored on a non-transitory computer readable storage medium. The computer program product includes computer-executable instructions, such as those included in program modules, being executed in a device on a target real or virtual processor, to carry out the process or method as described above with reference to FIGS. 1 to 11. Generally, program modules include routines, programs, libraries, objects, classes, components, data structures, or the like that perform particular tasks or implement particular abstract data types. The functionality of the program modules may be combined or split between program modules as desired in various embodiments. Machine-executable instructions for program modules may be executed within a local or distributed device. In a distributed device, program modules may be located in both local and remote storage media.

Program code for carrying out methods of the present disclosure may be written in any combination of one or more programming languages. These program codes may be provided to a processor or controller of a general purpose computer, special purpose computer, or other programmable data processing apparatus, such that the program codes, when executed by the processor or controller, cause the functions/operations specified in the flowcharts and/or block diagrams to be implemented. The program code may execute entirely on a machine, partly on the machine, as a stand-alone software package, partly on the machine and partly on a remote machine or entirely on the remote machine or server.

The above program code may be embodied on a machine readable medium, which may be any tangible medium that may contain, or store a program for use by or in connection with an instruction execution system, apparatus, or device. The machine readable medium may be a machine readable signal medium or a machine readable storage medium. A machine readable medium may include but not limited to an electronic, magnetic, optical, electromagnetic, infrared, or semiconductor system, apparatus, or device, or any suitable combination of the foregoing. More specific examples of the machine readable storage medium would include an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing.

Further, while operations are depicted in a particular order, this should not be understood as requiring that such operations be performed in the particular order shown or in sequential order, or that all illustrated operations be performed, to achieve desirable results. In certain circumstances, multitasking and parallel processing may be advantageous. Likewise, while several specific implementation details are contained in the above discussions, these should not be construed as limitations on the scope of the present disclosure, but rather as descriptions of features that may be specific to particular embodiments. Certain features that are described in the context of separate embodiments may also be implemented in combination in a single embodiment. Conversely, various features that are described in the context of a single embodiment may also be implemented in multiple embodiments separately or in any suitable sub-combination.

Although the present disclosure has been described in language specific to structural features and/or methodological acts, it is to be understood that the present disclosure defined in the appended claims is not necessarily limited to the specific features or acts described above. Rather, the specific features and acts described above are disclosed as example forms of implementing the claims.

1. A first device comprising:
a processor configured to cause the first device to:
truncate compressed bits corresponding to at least one layer of a plurality of layers until a first condition for stopping truncating compressed bits is met and based at least in part on at least one of the following:
truncation size information, indicating the number of compressed bits corresponding to the plurality of layers truncated during the truncating, or
effective length information, indicating the number of remaining compressed bits corresponding to the plurality of layers during the truncating;
transmit, to a second device, the CSI report comprising the truncated compressed bits.

2. The first device of claim 1, wherein the truncation size information comprises at least one of the following:
a truncation size, indicating the number of compressed bits truncated from compressed bits corresponding to a layer of the plurality of layers for each truncating operation, wherein the truncation size is either a common size configured for the plurality of layers or a specific size configured for one of the plurality of layers,
a truncation step size, indicating a difference of truncation sizes of two consecutive truncating operations, wherein the truncation step size is either a common size configured for the plurality of layers or a specific size configured for one of the plurality of layers, or
a set of truncation sizes, indicating a set of allowed truncation sizes for a layer, wherein the set of truncation sizes is either a common set configured for the plurality of layers or a specific set configured for one of the plurality of layers;
and wherein the effective length information comprises at least one of the following:
an effective length, indicating the number of allowed remaining compressed bits for a layer of the plurality of layers, wherein the effective length is either a common effective length configured for the plurality of layers or a specific effective length configured for one of the plurality of layers, or
a set of effective lengths, indicating a set of numbers of allowed remaining compressed bits for a layer of the plurality of layers, wherein the set of effective lengths is either a common set configured for the plurality of layers or a specific set configured for one of the plurality of layers.

3. The first device of claim 1, wherein the processor is further configured to cause the first device to:
iteratively truncate the compressed bits until the first condition is met,
and wherein for each truncating operation, compressed bits corresponding each layer are truncated based on one of the following:
a respective truncation size,
a truncation size comprised in a set of truncation sizes,
a respective effective length, or
an effective length comprised in a set of effective lengths.

4. The first device of claim 3, wherein,
truncation sizes for different layers are the same or different,
truncation sizes for different truncating operations are the same or different,
truncation step sizes for different layers are the same or different,
truncation step sizes for different truncating operations are the same or different,
effective lengths for different layers are the same or different, or
effective lengths for different truncating operations are the same or different.

5. The first device of claim 1, wherein the processor is further configured to cause the first device to:
truncate the compressed bits layer by layer according to a priority of layer by performing one of the following:
continuously truncating compressed bits corresponding to a layer of the plurality of layers until a second condition for stopping truncating compressed bits corresponding to the layer is met, or
truncating compressed bits corresponding to the plurality of layers in a manner of polling among the plurality of layers.

6. The first device of claim 1, wherein the processor is further configured to cause the first device to:
determine the total number of compressed bits to be truncated based on available resources configured for transmitting compressed bits and the total number of compressed bits of the plurality of layers; and
determine the number of compressed bits to be truncated for a layer of the plurality of layers based on the total number of compressed bits to be truncated and at least one of the following:
the number of layers,
a priority of layer,
the number of compressed bits corresponding to the layer,
the total number of compressed bits corresponding to the plurality of layers,
a maximum truncation size corresponding to the layer,
a common maximum truncation size corresponding to more than one layers,
a minimum allowed number of compressed bits corresponding to the layer, or
a common minimum allowed number of compressed bits corresponding to more than one layer.

7. The first device of claim 1, wherein the plurality of layers are corresponding to a plurality of sets of effective lengths, and wherein the processor is further configured to cause the first device to:
determine an effective length from a respective set of effective lengths for each layer, such that:
a sum value of a plurality of effective lengths corresponding to the plurality of layers meets requirements of available resources configured for transmitting compressed bits;
the sum value of the plurality of effective lengths is maximized; or
effective lengths for different layers correspond to a same effective length identifier.

8. The first device of claim 1, wherein the processor is further configured to cause the first device to:
omit remaining compressed bits corresponding to the plurality of layers layer by layer according to a priority of layer if:
the total number of remaining compressed bits corresponding to each of the plurality of layers satisfies a second condition for stopping truncating compressed bits corresponding to the layer; and
the total number of remaining compressed bits corresponding to the plurality of layers meets a third condition.

9. The first device of claim 1, wherein the processor is further configured to cause the first device to:
determine the first condition is met in response to at least one of the following:
the total number of remaining compressed bits corresponding to the plurality of layers satisfies the requirements of available resources for transmitting compressed bits, or
for each of the plurality of layers, the number of remaining compressed bits meets a second condition for stopping truncating compressed bits corresponding to a layer.

10. The first device of claim 1, wherein the processor is further configured to cause the first device to:
determine a second condition for stopping truncating compressed bits corresponding to a layer is met in response to at least one of the following:
all compressed bits corresponding to the layer have been truncated, or
the number of remaining compressed bits corresponding to the layer is equal to or smaller than a threshold number.

11. The first device of claim 1, wherein any of the truncation size information and the effective length information is determined based on at least one of the following:
a rank indicator,
an index of a layer,
parity of an index of a layer,
the number of compressed bits corresponding to a layer,
a truncation ratio,
model-related information associated with a layer,
quantization-related information associated with a layer, or
CSI payload information associated with a layer.

12. The first device of claim 1, wherein a priority of a layer of the plurality of layers is determined based on at least one of the following:
an index of a layer,
parity of an index of a layer,
quality of a layer,
the number of compressed bits corresponding to a layer,
model-related information associated with a layer,
quantization information associated with a layer, or
CSI payload information associated with a layer.

13. The first device of claim 11 or 12, wherein the model-related information comprises at least one of the following:
an identity of a model,
model description information,
data information corresponding to a mode,
performance of a model,
a configuration associated with a model,
a scenario associated with a model
a site associated with a model, or
a cell associated with a model.

14. The first device of claim 11 or 12, wherein the quantization-related information comprises at least one of the following:
an identity of a quantization,
a type of quantization,
a size of segment for vector quantization,
the number of segments for vector quantization,
information related to a codebook of quantization for vector quantization,
the number of quantization bits,
the number of quantization bits per segment for vector quantization,
a quantization granularity, or
performance of quantization.

15. The first device of claim 11 or 12, wherein the CSI payload information comprises at least one of the following:
an indication indicating a CSI payload size,
an indication indicating a size of compressed bits,
an indication indicating a size of second part of a CSI report, or
an indication indicating a compression ratio.

16. The first device of claim 1, wherein the processor is further configured to cause the first device to:
receive from the second device, configuration information for a channel status information (CSI) report, the configuration information indicating at least one of the following:
an indication used for enabling or disabling truncating the compressed bits corresponding to the plurality of layers,
the truncation size information, or
the effective length information.

17. The first device of claim 1, wherein the configuration information is comprised in at least one of the following:
a radio resource control (RRC) signalling,
a medium access control (MAC) control element (CE), or
downlink control information (DCI).

18. The first device of claim 1, wherein the processor is further configured to cause the first device to:
transmit capability-related information of the first device to the second device, the capability-related information indicating at least one of the following:
a first capability indicating whether the first device supports truncating the compressed bits,
a second capability indicates the maximum or minimum value of a truncation size supported by the first device,
a third capability indicates the maximum or minimum value of a truncation step size supported by the first device, or
a fourth capability indicates the maximum or minimum value of an effective length supported by the first device.

19. The first device of claim 1, wherein a first part of the CSI report comprises at least one of the following:
information about whether the truncating is performed,
information about identifier of one or more truncated layers,
information about the number of times truncating operations,
information about a truncation size used by the first device,
information about a truncation step size used by the first device, or
information about an effective length used by the first device.

20. The first device of claim 1, wherein the processor is further configured to cause the first device to:
truncate the compressed bits according to an order of from right to left or from the least significant bit (LSB) to the most significant bit (MSB).
